(19) United States
(12) Patent Application Publication
(10) Pub. No.: US 2025/0294954 A1
(43) Pub. Date: Sep. 18, 2025

(54) DISPLAY DEVICE

(71) Applicant: Samsung Display Co., LTD., Yongin-si (KR)

(72) Inventors: KANGBIN JO, Yongin-si (KR); ILNAM KIM, Yongin-si (KR); JUNGWOO PARK, Yongin-si (KR); HYUNDAE LEE, Yongin-si (KR); SEUNGHYUN MOON, Yongin-si (KR); GOEUN CHA, Yongin-si (KR)

(21) Appl. No.: 18/999,864

(22) Filed: Dec. 23, 2024

(30) Foreign Application Priority Data
Mar. 18, 2024 (KR) 10-2024-0036858

(51) Int. Cl. H10K 39/34; G06V 40/13; G09G 3/3233; H10K 59/123; H10K 59/38; H10K 59/80

(52) U.S. Cl. CPC H10K 39/34; H10K 59/123; H10K 59/8792; G06V 40/1318; G09G 3/3233; G09G 2300/0426; G09G 2300/0819; G09G 2300/0842; H10K 59/38

(57) ABSTRACT

A display device includes a display panel including a display area defined therein. The display panel includes a pixel including a pixel driving circuit and a light-emitting element and a first sensor including a first sensor driving circuit and a first sensing element, where the first sensing element includes a first electrode electrically connected to the first sensor driving circuit, a semiconductor layer electrically disconnected from the first electrode, and a second electrode electrically connected to the semiconductor layer, and the light-emitting element is electrically connected to the pixel driving circuit and the second electrode.

This application claims priority to Korean Patent Application No. 10-2024-0036858, filed on Mar. 18, 2024, and all the benefits accruing therefrom under 35 U.S.C. § 119, the content of which in its entirety is herein incorporated by reference.

### BACKGROUND

### (1) Field

Embodiments of the disclosure herein relate to a display device with improved sensing reliability.

### (2) Description of the Related Art

A display device displays an image to provide information to a user or provide various functions capable of organically communicating with a user, such as sensing an input of the user. Recently, display devices typically include a function for sensing information (e.g., biometric information or the like) provided by a user. In addition, display devices may also include a function for sensing the illuminance of the surroundings. Namely, the display device includes a sensor for sensing a fingerprint and/or illuminance. In such a display device, an electrostatic capacitive manner for sensing a change in electrostatic capacitance provided between electrodes, an optical manner for sensing incident light using an optical sensor, or an ultrasonic wave manner for sensing vibration using a piezoelectric body, etc. may be used as a user information recognition manner.

### SUMMARY

Embodiments of the disclosure provide a display device with improved sensing reliability.

An embodiment of the invention provides a display device including: a display panel including a display area defined therein, where the display panel includes a pixel including a pixel driving circuit and a light-emitting element and a first sensor including a first sensor driving circuit and a first sensing element, where the first sensing element includes a first electrode electrically connected to the first sensor driving circuit, a semiconductor layer electrically disconnected from the first electrode, and a second electrode electrically connected to the semiconductor layer, and wherein the light-emitting element is electrically connected to the pixel driving circuit and the second electrode.

In an embodiment, the display panel may further include a second sensor including a second sensor driving circuit and a second sensing element different from the first sensing element, a first area and a second area adjacent to the first area may be defined in the display area, and the second sensor may be disposed in the first area.

In an embodiment, the second sensing element may include a first electrode electrically connected to the second sensor driving circuit, a semiconductor layer electrically connected to the first electrode, and a second electrode electrically connected to the semiconductor layer.

In an embodiment, the first sensor may be disposed in the second area.

In an embodiment, the second sensor driving circuit may include: a second reset transistor including a gate electrode which receives a reset control signal, a first electrode which receives a first reset voltage, and a second electrode connected to a first sensing node therein; a second amplification transistor including a first electrode which receives a sensor driving voltage, a second electrode connected to a second sensing node therein, and a gate electrode connected to the first sensing node therein; and a second output transistor including a first electrode connected to the second sensing node therein, a second electrode connected to a readout line, and a gate electrode which receives an output control signal.

In an embodiment, the first sensor driving circuit may include: a first reset transistor including a gate electrode which receives the reset control signal, a first electrode, and a second electrode connected to a first sensing node therein; a first amplification transistor including a first electrode which receives the sensor driving voltage, a second electrode connected to a second sensing node therein, and a gate electrode connected to the first sensing node therein; and a first output transistor including a first electrode connected to the second sensing node therein, a second electrode connected to the readout line, and a gate electrode which receives the output control signal.

In an embodiment, the first reset voltage may be provided to the first electrode of the first reset transistor.

In an embodiment, a second reset voltage having a different voltage level from the first reset voltage may be provided to the first electrode of the first reset transistor.

In an embodiment, the first sensor driving circuit may include: a first amplification transistor including a first electrode which receives the sensor driving voltage, a second electrode connected to a second sensing node therein, and a gate electrode connected to a second reset voltage having a different voltage level from the first reset voltage; and a first output transistor including a first electrode connected to the second sensing node therein, a second electrode connected to the readout line, and a gate electrode which receives the output control signal.

In an embodiment, the display device may further include: an anti-reflection layer disposed on the display panel, where the anti-reflection layer includes: a black matrix layer having a first opening overlapping the light-emitting element therein when viewed in a plan view; and a color filter layer disposed on the first opening.

In an embodiment, when viewed in the plan view, a second opening overlapping the second sensing element may be defined in a black matrix layer.

In an embodiment, when viewed in the plan view, a third opening overlapping the first sensing element may be defined in the black matrix layer.

In an embodiment, when viewed in the plan view, the black matrix layer may overlap the first sensing element.

In an embodiment, the first area may include a first first area and a second first area disposed between the first first area and the second area, a second opening overlapping with the second sensing element may be defined in the black matrix layer in the first first area, and the black matrix layer may overlap with the second sensing element in the second first area.

In an embodiment, a third area adjacent to the first area and the second area may be defined in the display area, and each of the first sensor and the second sensor may be spaced apart from the third area.

In an embodiment of the invention, a display device includes: a base layer; a circuit layer disposed on the base layer and including a pixel driving circuit and a first sensor driving circuit; an element layer disposed on the circuit layer and including a light-emitting element, a first sensing element, and a pixel definition layer; and an encapsulation layer disposed on the element layer, wherein the first sensing element includes a first electrode disposed on the circuit layer and covered with the pixel definition layer, a semiconductor layer disposed on the pixel definition layer, and a second electrode covering the semiconductor layer.

In an embodiment, a first area and a second area adjacent to the first area may be defined in the base layer, and the first sensor driving circuit and the first sensing element may be disposed in the second area.

In an embodiment, the first sensor driving circuit may include: a first reset transistor including a gate electrode which receives a reset control signal, a first electrode, and a second electrode connected to a first sensing node therein; a second amplification transistor including a first electrode which receives a sensor driving voltage, a second electrode connected to a second sensing node therein, and a gate electrode connected to the first sensing node therein; and a first output transistor including a first electrode connected to the second sensing node therein, a second electrode connected to a readout line, and a gate electrode which receives an output control signal.

In an embodiment, a first reset voltage may be provided to the first electrode of the first reset transistor.

In an embodiment, the first sensor driving circuit may include: a first amplification transistor including a first electrode which receives a sensor driving voltage, a second electrode connected to a second sensing node therein, and a gate electrode which receives a second reset voltage; and a first output transistor including a first electrode connected to the second sensing node therein, a second electrode connected to the readout line, and a gate electrode which receives an output control signal.

### BRIEF DESCRIPTION OF THE DRAWINGS

The above and other features of embodiments of the invention will become more apparent by describing in further detail embodiments thereof with reference to the accompanying drawings, in which:

FIG. 1 is a perspective view of a display device according to an embodiment of the invention;

FIG. 2 is a cross-sectional view showing a portion of a display device according to an embodiment of the invention;

FIG. 3 is a block diagram of a display device according to an embodiment of the invention;

FIG. 4 is a plan view of a display area of a display panel according to an embodiment of the invention;

FIG. 5A is a cross-sectional view of the display device taken along line I-I′ of FIG. 4 according to an embodiment of the invention;

FIG. 5B is an equivalent circuit diagram of a pixel and a first sensor according to an embodiment of the invention;

FIG. 6A is a cross-sectional view of the display device taken along line II-II′ of FIG. 4 according to an embodiment of the invention;

FIG. 6B is an equivalent circuit diagram of a pixel and a second sensor according to an embodiment of the invention;

FIG. 7 is a cross-sectional view of a display device taken along line I-I′ of FIG. 4 according to another embodiment of the invention;

FIG. 8 is a plan view of a display area of a display panel according to an embodiment of the invention;

FIG. 9A is a cross-sectional view of the display device taken along line III-III′ of FIG. 8 according to an embodiment of the invention;

FIG. 9B is an equivalent circuit diagram of a pixel and a second sensor according to an embodiment of the invention;

FIG. 10 is a plan view of a display area of a display panel according to an embodiment of the invention;

FIG. 11 is an equivalent circuit diagram of a pixel and a first sensor according to an embodiment of the invention; and

FIG. 12 is an equivalent circuit diagram of a pixel and a first sensor according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element or layer is referred to as being “on”, “connected to” or “coupled to” another element or layer, it can be directly on, connected or coupled to the other element or intervening third elements may be present therebetween. In contrast, when an element is referred to as being “directly on” another element, there are no intervening elements present.

Like reference numerals in the drawings refer to like elements. In addition, in the drawings, the thickness and the ratio and the dimension of the element are exaggerated for effective description of the technical contents.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

In addition, the terms such as “under”, “lower”, “on”, and “upper” are used for explaining associations of items illustrated in the drawings. The terms are used as a relative concept and are described with reference to the direction indicated in the drawings.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this disclosure belong. In addition, it will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described with reference to the accompanying drawings.

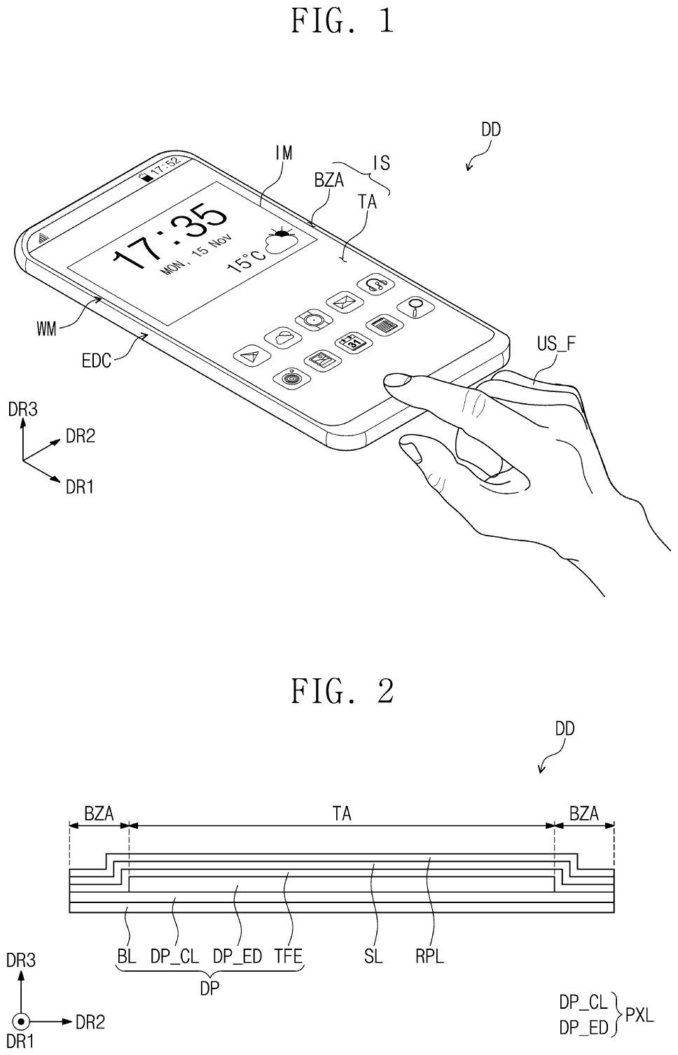

FIG. 1 is a perspective view of a display device according to an embodiment of the invention.

Referring to FIG. 1, an embodiment of the display device DD may be a mobile phone, a tablet computer, a vehicle, a navigator, a game device, or a wearable device, but is not limited thereto. In FIG. 1, an embodiment where the display device DD is a mobile phone is shown as an example.

In FIG. 1, an embodiment where the display device DD is a bar-shaped rigid type display device DD is shown as an example, but is not limited thereto. In another embodiment, for example, the display device DD may have a foldable, rollable, or slidable type.

The top surface of the display device DD be defined as a display surface IS, and the display surface IS may be on a plane defined by a first direction DR1 and a second direction DR2. Images IM generated in the display device DD may be provided to a user through the display surface IS.

Hereinafter, a normal direction substantially vertical to the plane defined by the first direction DR1 and the second direction DR2 is defined as a third direction DR3. The third direction DR3 may be a thickness direction. In the specification, “when viewed in a plan view” may mean a state of being viewed in the third direction DR3. Namely, the plane may be parallel to a surface defined by the first direction DR1 and the second direction DR2.

In an embodiment, the display surface IS may be divided into a transmission area TA and a bezel area BZA. The transmission area TA may be an area in which the image IM is displayed. No image may be displayed on the bezel area BZA. A user views the image IM via the transmission area TA. In an embodiment, as shown in FIG. 1, the transmission area TA may be in a rectangle shape with rounded edges. However, this is merely an example, and the transmission area TA may have various shapes such as a rectangle, circle, or square, and is not limited to any one embodiment.

The bezel area BZA is adjacent to the transmission area TA. The bezel area BZA may have a prescribed color. In an embodiment, the bezel area BZA may surround the transmission area TA. Accordingly, the shape of the image area TA may be substantially defined by the bezel area BZA. However, this is merely an example. In another embodiment, the bezel area BZA may be disposed adjacent only to one side of the transmission area TA, or may be omitted.

The display device DD may detect an external input applied from an outside. The external input may include various types of inputs provided from the outside of the display device DD. In an embodiment, for example, the external input may include an external input (e.g., a hovering input) applied close to or in proximity to the display device DD at a predetermined distance as well as a touch input using a user's body part US_F. In addition, the external input may have various types such as force, pressure, temperature, or light, etc. The external input may be provided by a separate device, for example, an active pen or a digitizer pen. Furthermore, the display device DD may detect the user's biometric information applied from the outside or measure the brightness of the surroundings.

The appearance of the display device DD may be composed of a window WM and a housing EDC. In an embodiment, for example, the window WM and the housing EDC may be combined to each other, and other components of the display device DD such as a display module DM may be accommodated therein.

The front surface of the window WM defines the display surface IS of the display device DD. The window WM may include an optically transparent insulation material. In an embodiment, for example, the window WM may include glass or plastics. The window WM may have a multilayer structure or a single-layer structure. In an embodiment, for example, the window WM may include a plurality of plastic films bonded with an adhesive, or a glass substrate and plastic films bonded with an adhesive.

The housing EDC may include a material with relatively high hardness. For example, the housing EDC may include a plurality of frames and/or plates including glass, plastic, metal, or a combination thereof. The housing EDC may stably protect components of the display device DD accommodated therein from an external impact. Although not shown in the figure, a battery module or the like configured to supply power used for the overall operations of the display device DD may be disposed between the display module DM and the housing EDC.

FIG. 2 is a cross-sectional view showing a portion of a display device according to an embodiment of the invention.

Referring to FIG. 2, an embodiment of the display device DD may include a display panel DP, a sensor layer SL, and an anti-reflection layer RPL.

The display panel DP may be a component configured to substantially generate the images IM (see FIG. 1). The display panel DP may be an emissive display panel, for example, an organic light-emitting display panel, an inorganic light-emitting display panel, an organic-inorganic light-emitting display panel, a quantum dot display panel, a micro-light emitting diode (LED) display panel, or a nano LED display penal. Hereinafter, for convenience of description, embodiments where the display panel DP is an organic light emitting display panel will be mainly described, but not being limited thereto.

The display panel DP may include a base layer BL, a pixel layer PXL, and an encapsulation layer TFE. The display panel DP according to an embodiment of the invention may be a flexible display panel DP or a rigid display panel. In an embodiment, for example, the display panel DP may be a foldable display panel folded around a folding axis, a rollable display panel, at least a portion of which is rolled around a rolling axis, or a slidable display panel.

The base layer BL may include a synthetic resin layer. The synthetic resin layer may be a polyimide-based resin layer, but the material is not particularly limited. In addition, the base layer BL may include a glass substrate, a metal substrate, or an organic/inorganic composite material substrate, etc.

The pixel layer PXL may be disposed on the base layer BL. The pixel layer PXL may include a circuit layer DP_CL and an element layer DP_ED.

The circuit layer DP_CL is disposed between the base layer BL and the element layer DP_ED. The circuit layer DP-CL includes at least one insulation layer and a circuit element. Hereinafter, the insulation layer included in the circuit layer DP-CL is referred to as an intermediate insulation layer. The intermediate insulation layer includes at least one intermediate inorganic film and at least one intermediate organic film.

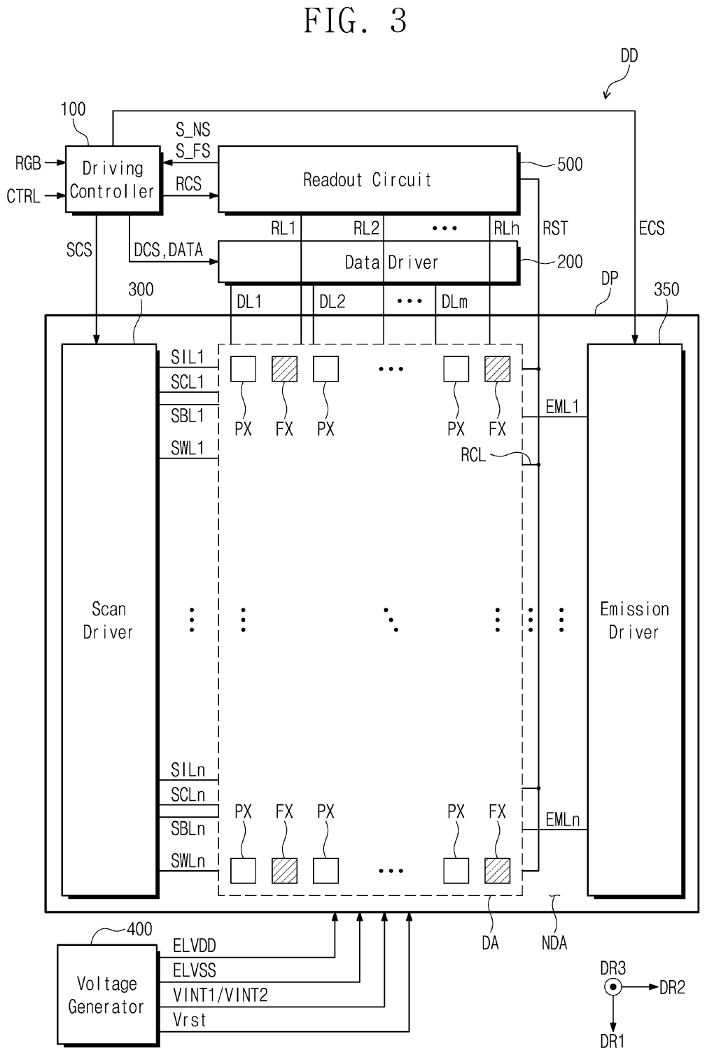

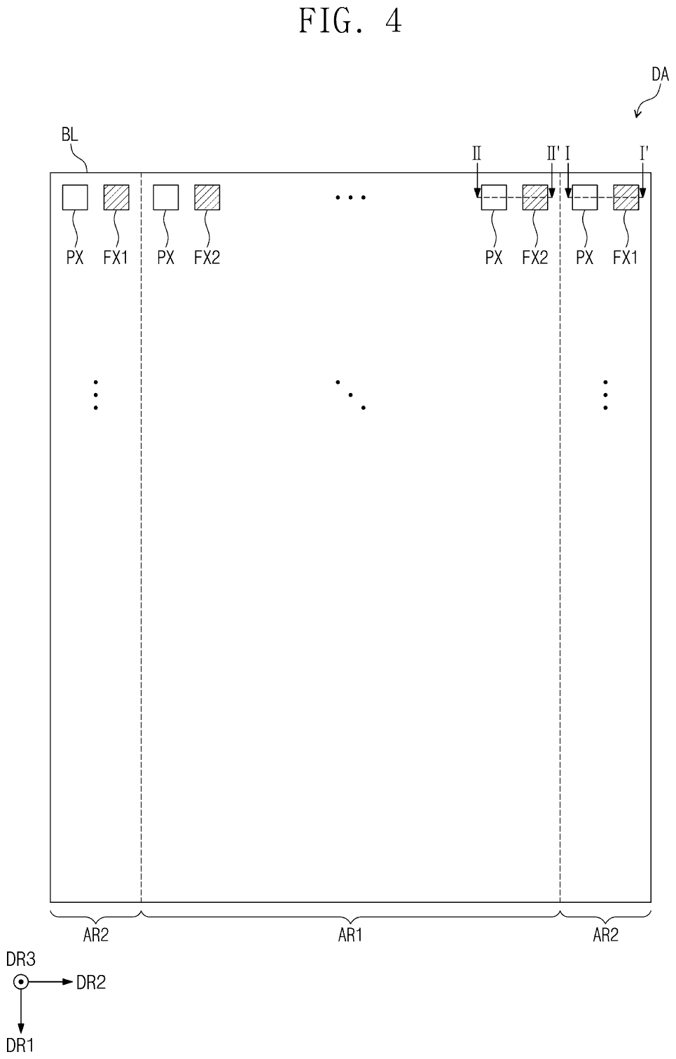

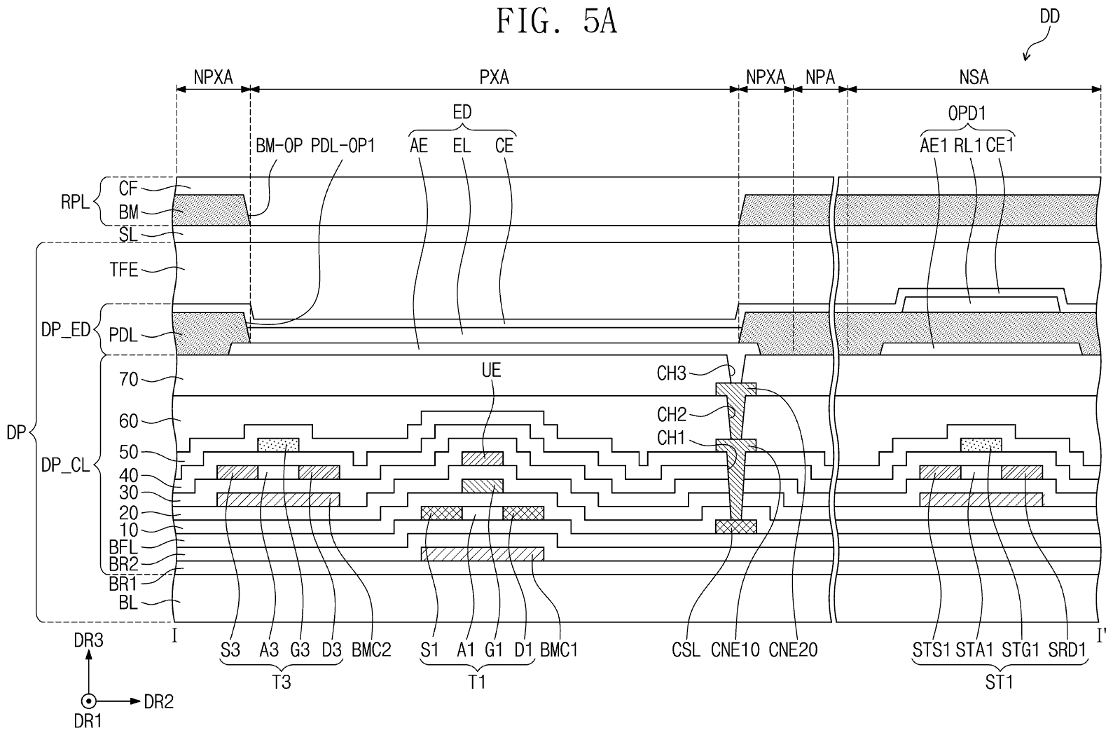

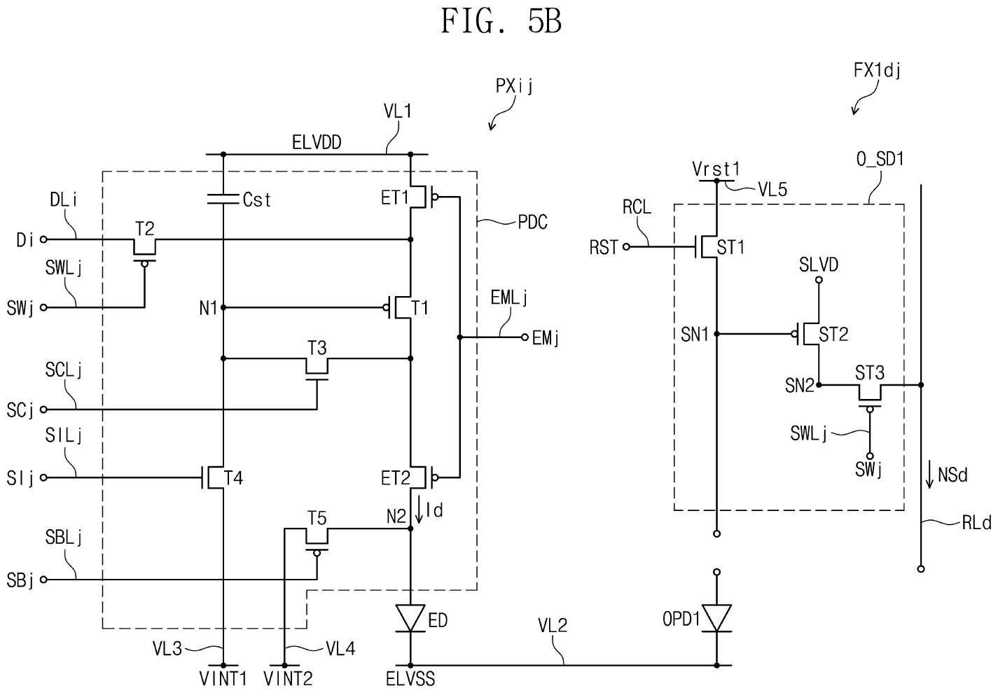

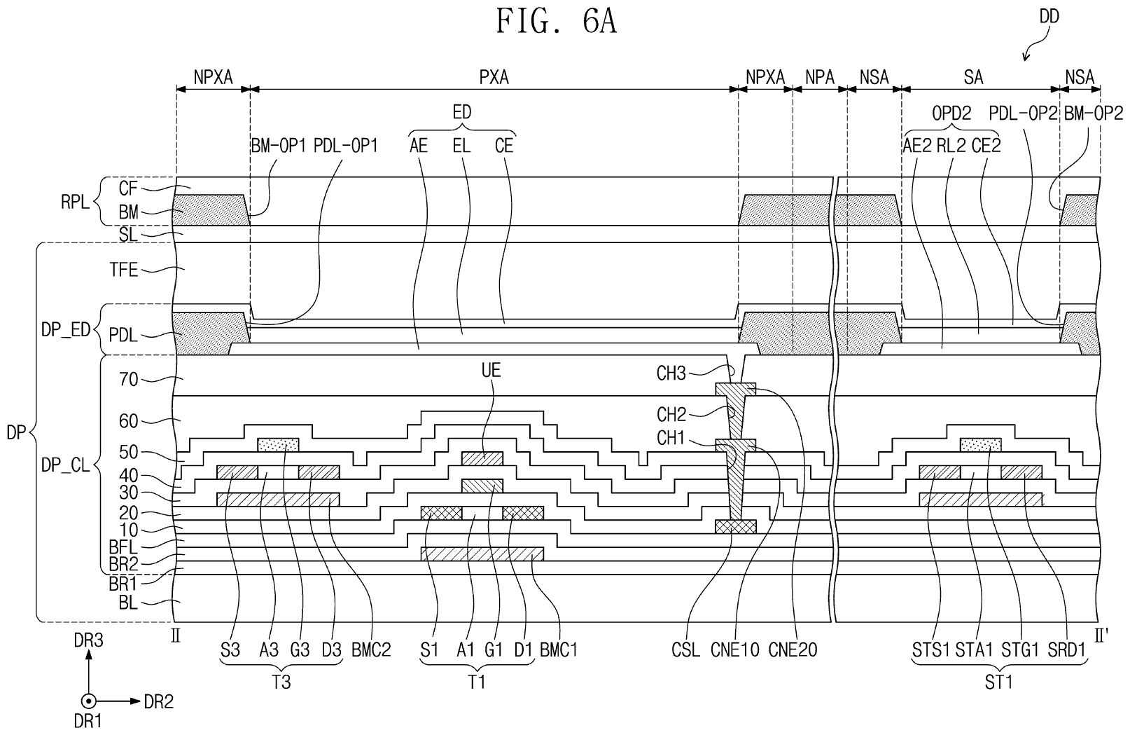

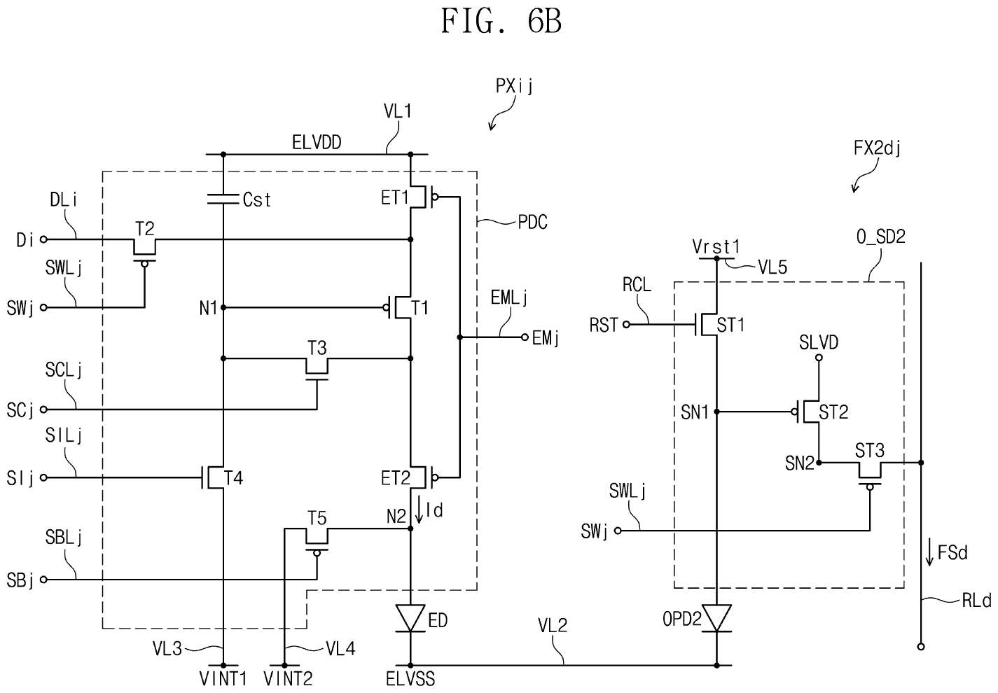

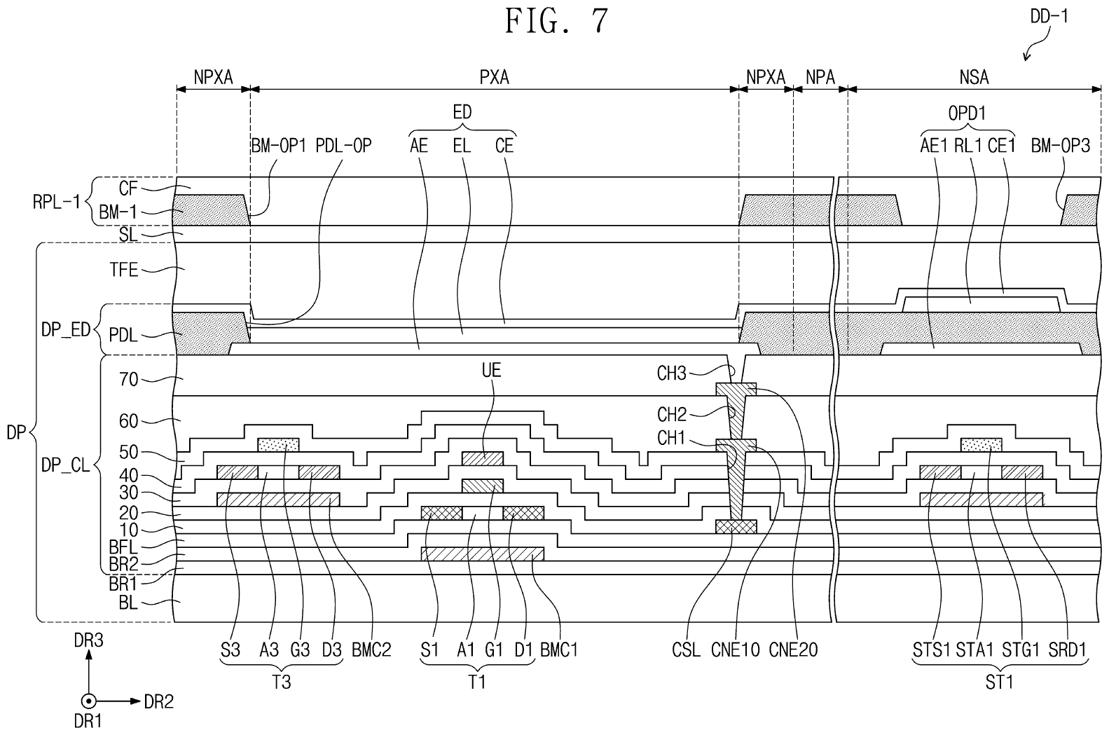

The circuit element may include a pixel driving circuit PDC (see FIG. 5B) included in each of a plurality of pixels PX (see FIG. 3) for displaying an image, and a first sensor driving circuit O_SD1 (see FIG. 5B) and a second sensor driving circuit O_SD2 (see FIG. 6B) included in a plurality of sensors FX (see FIG. 3) for recognizing external information. The circuit layer DP_CL may further include signal lines connected to the pixel driving circuit PDC (see FIG. 5B) and/or the first sensor driving circuit O_SD1 (see FIG. 5B) and the second sensor driving circuit O_SD2 (see FIG. 6B). In an embodiment, the plurality of sensors FX may include a first sensor FX1 (see FIG. 4) disposed in a second section AR2 (see FIG. 4) and a second sensor FX2 (see FIG. 4) disposed in a first section AR1 (see FIG. 4), and the description will be described below.

The element layer DP_ED may include a light-emitting element ED (see FIG. 5B) included in each of the plurality of pixels PX and a first sensing element DPD1 (see FIG. 5A) and a second sensing element OPD2 (see FIG. 6A) included in the plurality of sensors FX. In an embodiment, for example, a first sensing element OPD1 (see FIG. 5A) and the second sensing element OPD2 (see FIG. 6A) each may be a photo diode, for example, an organic photo diode. The second sensing element OPD2 (see FIG. 6A) may be a sensor configured to detect or react to light reflected by a fingerprint of a user. The circuit layer DP_CL and the element layer DP_ED will be described in greater detail below.

The encapsulation layer TFE is disposed on the element layer DP_ED to encapsulate the element layer DP_ED. The encapsulation layer TFE may include at least one inorganic film and one organic film. The inorganic film may include an inorganic material and protect the pixel layer DP_ED from moisture/oxygen. The inorganic film may include a silicon nitride layer, a silicon oxynitride layer, a silicon oxide layer, a titanium oxide layer, an aluminum oxide layer or the like, but is not particularly limited thereto. The organic layer may include an organic material and protect the element layer DP_EL from foreign matters such as dust particles.

The sensor layer SL may be disposed on the display panel DP. The sensor layer SL may be provided or formed on the display panel DP through successive processes, but the invention is not limited thereto. The sensing layer SL may sense the coordinates of an external input.

The anti-reflection layer RPL may be disposed on the sensor layer SL. The anti-reflection layer RPL may reduce a reflectance of external light incident from the outside.

The anti-reflection layer RPL may include a color filter layer CF (see FIG. 5A), a black matrix BM (see FIG. 5A), and a planarization layer. The color filter layer CF (see FIG. 5A) may have a prescribed array. In an embodiment, for example, the color filter layer CF (see FIG. 5A) may be arranged in consideration of emission colors of the pixels included in the display panel DP. In another embodiment, the anti-reflection layer RPL may include a black matrix BM (see FIG. 5A) and a reflection control layer. The anti-reflection layer RPL may selectively absorb light in a partial band of light reflected inside the display panel DP and/or an electronic apparatus, or light incident from outside the display panel and/or the electronic apparatus. In another embodiment, the anti-reflection layer RPL may be a polarization film.

FIG. 3 is a block diagram of a display device according to an embodiment of the invention.

Referring to FIG. 3, an embodiment of the display device DD includes the display panel DP, a panel driver (or referred to as a driving circuit), and a driving controller 100. In an embodiment, for example, the panel driver includes a data driver 200, a scan driver 300, an emission driver 350, a voltage generator 400, and a readout circuit 500.

The display panel DP may include a display area DA corresponding to the transmission area TA (see FIG. 1) and a non-display area NDA correspond to the bezel area BZA (see FIG. 1).

The display panel DP may include a plurality of pixels PX disposed in the display area DA and a plurality of sensors FX disposed in the display area DA In an embodiment, for example, each of the plurality of sensors FX may be disposed between two adjacent pixels PX. The plurality of pixels PX and the plurality of sensors FX may be alternately disposed in the first and second directions DR1 and DR2. However, the embodiment of the invention is not limited thereto. In another embodiment, two or more pixels may be disposed between two sensors FX adjacent in the first direction DR1 among the plurality of sensors FX, or between two sensors FX adjacent in the second direction DR2 among the plurality of sensors FX.

The display panel DP further includes initialization scan lines SIL1 to SILn, compensation scan lines SCL1 to SCLn, write scan lines SWL1 to SWLn, black scan lines SBL1 to SBLn, emission control lines EML1 to EMLn, data lines DL1 to DLm, and readout lines RL1 to RLh. Here, n, m and h are integers greater than 2.

The initialization scan lines SIL1 to SILn, the compensation scan lines SCL1 to SCLn, the write scan lines SWL1 to SWLn, the black scan lines SBL1 to SBLn, and the emission control lines EML1 to EMLn extend in the second direction DR2. The initialization scan lines SIL1 to SILn, the compensation scan lines SCL1 to SCLn, the write scan lines SWL1 to SWLn, the black scan lines SBL1 to SBLn, and the emission control lines EML1 to EMLn are spaced apart from each other in the first direction DR1. The data lines DL1 to DLm and readout lines RL1 to RLh extend in the first direction DR1 and are spaced apart from each other in the second direction DR2.

The plurality of pixels PX are respectively electrically connected to the initialization scan lines SIL1 to SILn, the compensation scan lines SCL1 to SCLn, the write scan lines SWL1 to SWLn, the black scan lines SBL1 to SBLn, the emission control lines EML1 to EMLn, and data lines DL1 to DLm. In an embodiment, for example, each of the plurality of pixels PX may be electrically connected to four scan lines. However, the number of scan lines connected to each of the pixels PX is not limited thereto, and may vary.

The plurality of sensors FX are respectively electrically connected to the readout lines RL1 to RLh. One sensor FX may be electrically connected to one scan line, for example, one of the write scan lines SWL1 to SWLn. However, the embodiment of the invention is not limited thereto. The number of scan lines connected to each of the sensors FX may be variable.

In an embodiment, for example, the number of readout lines RL1 to RLh may correspond to half the number of the data lines DL1 to DLm. However, the embodiment of the invention is not limited thereto. Alternatively, the number of readout lines RL1 to RLh may correspond to about ¼ or about ⅛ of the number of the data lines DL1 to DLm.

The driving controller 100 receives an image signal RGB and a control signal CTRL. The driving controller 100 generates an image data signal DATA with a converted data format of the image signal RGB to satisfy the interface specification with the data driver 200. The driving controller 100 may output a first control signal SCS, a second control signal ECS, a third control signal DCS, and a fourth control signal RCS based on the control signal CTRL.

The data driver 200 may receive the third control signal DCS and the image data signal DATA from the driving controller 100. The data driver 200 converts the image data signal DATA into data signals, and outputs the data signals to the plurality of data lines DL1 to DLm to be described below. The data signals have analog voltages corresponding to grayscale values of the image data signal DATA.

The scan driver 300 receives the first control signal SCS from the driving controller 100. The scan driver 300 may output scan signals to scan lines in response to the first control signal SCS. In an embodiment, for example, in response to the first control signal SCS, the scan driver 300 outputs initialization scan signals to the initializations scan lines SIL1 to SILn, and compensation scan signals to the compensation scan lines SCL1 to SCLn. In addition, in response to the first control signal SCS, the scan driver 300 may output write scan signals to the write scan lines SWL1 to SWLn, and black scan signals to the black scan lines SBL1 to SBLn.

The scan driver 300 may be disposed in the non-display area NDA of the display panel DP. However, the embodiment is not limited thereto. In an embodiment, for example, at least a portion of the scan driver 300 may also be disposed in the display area DA.

The emission driver 350 may be disposed in the non-display area NDA of the display panel DP. The emission driver 350 receives the second control signal ECS from the driving controller 100. In response to the second control ECS, the emission driver 350 may output emission control signals to the emission control lines EL1 to ELn. Alternatively, the scan driver 300 may be connected to the emission control lines EML1 to EMLn. In this case, the emission driver 350 may be omitted, and the scan driver 300 may output the emission control signals to the emission control lines EML1 to EMLn.

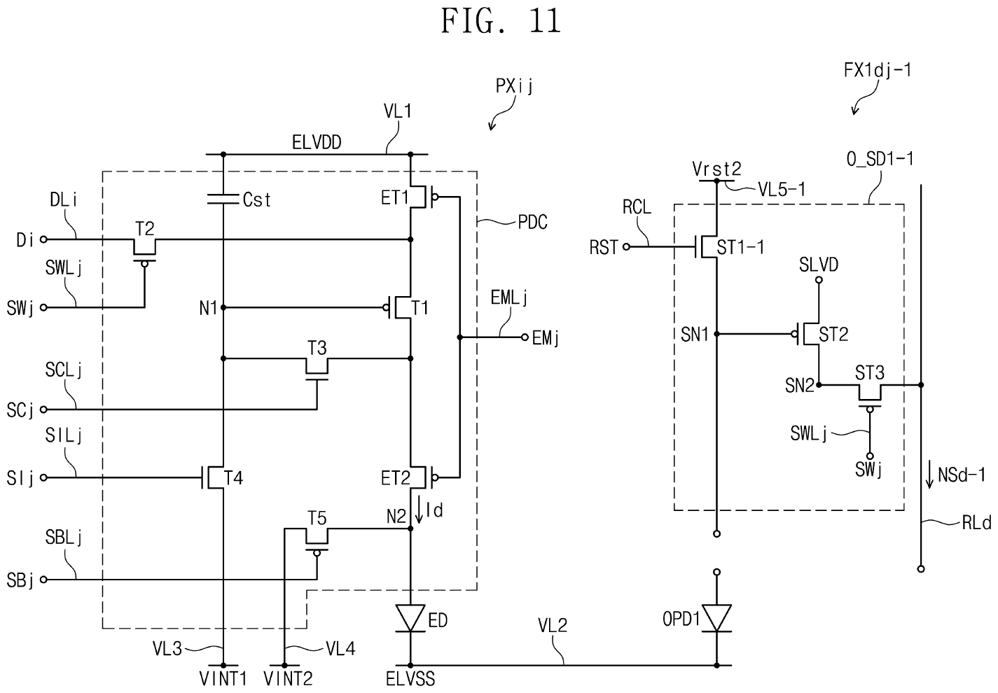

The voltage generator 400 generates voltages required for operations of the display panel DP. In an embodiment, the voltage generator 400 generates a first driving voltage ELVDD, a second driving voltage ELVSS, a first initialization voltage VINT1, a second initialization voltage VINT2, and a reset voltage Vrst. The rest voltage Vrst may include a first reset voltage Vrst1 (see FIG. 5B) and a second reset voltage Vrst2 (see FIG. 11) having a different voltage level from the first reset voltage Vrst1. The detailed description thereof will be provided below.

The readout circuit 500 receives the fourth control signal RCS from the driving controller 100. The readout circuit 500 may receive sensing signals from the readout lines RL1 to RLh in response to the fourth control signal RCS. The readout circuit 500 may process the sensing signals and noise signals received from the readout lines RL1 to RLh, and provide the processed sensing signals S_FS and the processed noise signals S_NS to the driving controller 100. The processed noise signals S_NS may be referred to as noise-processed signals S_NS. The noise-processed signals S_NS may be signals obtained by processing noise signals NSd (see FIG. 5B) generated in the first drive circuit O_SD1 (see FIG. 5B).

The readout circuit 500 may provide the reset control signal RST to the sensor FX through a reset control line RCL. In an embodiment, for example, the reset control signal RST may be provided to a reset transistor ST1 (see FIG. 5B) of the sensor FX to turn on the reset transistor ST1.

FIG. 4 is a plan view of a display area of a display panel according to an embodiment of the invention. In describing the embodiment of FIG. 4, like reference numerals are given to like elements shown in FIG. 3, and any repetitive detailed description thereof will be omitted.

Referring to FIG. 4, in an embodiment, the display area DA may include a first area AR1 and a second area AR2. When viewed in a plan view or viewed in the third direction DR3, the base layer BL may overlap the display area DA. The display area DA may be defined in the base layer BL. A first area AR1 and a second area AR2 may be defined in the base layer BL.

The second area AR2 may be provided in plural. One of the plurality of second areas AR2 may be positioned proximally from the first area AR1 in the opposite direction to the second direction DR2. Another one of the plurality of second areas AR2 may be positioned proximally from the first area AR1 in the second direction DR2. In such an embodiment, the first area AR1 may be positioned between the plurality of second areas AR2.

The plurality of pixels PX and the plurality of second sensors FX2 may be disposed in the first area AR1.

The plurality of pixels PX and the plurality of first sensors FX1 may be disposed in the second area AR2.

FIG. 5A is a cross-sectional view of the display device taken along line I-I′ of FIG. 4 according to an embodiment of the invention. In describing the embodiment of FIG. 5B, like reference numerals are given to like elements shown in FIG. 2, and any repetitive detailed description thereof will be omitted.

Referring to FIG. 5A, an embodiment of the display device DD may include a display panel DP, a sensor layer SL, and an anti-reflection layer RPL. The display panel DP may include a base layer BL, a circuit layer DP_CL, an element layer DP_ED, and an encapsulation layer TFE.

At least one inorganic layer is provided on the top surface of the base layer BL. The inorganic layer may include at least one selected from aluminum oxide, titanium oxide, silicon oxide, silicon oxynitride, zirconium oxide, or hafnium oxide. The inorganic layer may be provided with multiple layers or have a multilayer structure. The multilayer inorganic layer may include barrier layers BR1 and BR2, and/or a buffer layer BFL to be described below. The barrier layers BR1 and BR2, and the buffer layer BFL may be selectively provided or omitted.

The barrier layers BR1 and BR2 may effectively prevent a foreign matter from entering from the outside. The barrier layers BR1 and BR2 each may include a silicon oxide layer and a silicon nitride layer. Each of the barrier layers BR1 and BR2 may be provided in plural, and the silicon oxide layers and the silicon nitride layers may be alternately laminated on each other.

The barrier layers BR1 and BR2 may include a first barrier layer BR1 and a second barrier layer BR2. A first rear-surface metal layer BMC1 may be disposed between the first barrier layer BR1 and the second barrier layer BR2. In an embodiment of the invention, the first rear-surface metal layer BMC1 may be omitted.

The buffer layer BFL may be disposed on the barrier layers BR1 and BR2. The buffer layer BFL may enhance a bonding force between the base layer BL and a semiconductor pattern and/or a conductive pattern. The barrier layer BFL may include silicon oxide layers and silicon nitride layers. The silicon oxide layers and the silicon nitride layers may be alternately laminated on each other.

The first semiconductor pattern may be disposed on the buffer layer BFL. The first semiconductor pattern may include a silicon semiconductor. In an embodiment, for example, the silicon semiconductor may include amorphous silicon, polycrystalline silicon, or the like. In an embodiment, for example, the first semiconductor pattern may include low temperature polysilicon.

FIG. 5A merely illustrates a portion of a first semiconductor pattern disposed on the buffer layer BFL, and the other portion of the first semiconductor pattern may be further disposed in another area. The first semiconductor pattern may be arranged in a specific rule across pixels. The first semiconductor pattern may have different electrical properties according to whether it is doped or not. The first semiconductor pattern may include a first area having high conductivity and a second area having low conductivity. The first area may be doped with an N-type dopant or a P-type dopant. A P-type transistor includes a doped region doped with a P-type dopant, and an N-type transistor includes a doped area doped with an N-type dopant. The second area may be a non-doped area, or be doped at a lower concentration than the first area.

The first area may have greater conductivity than the second area, and substantially serve as an electrode or a signal line. The second area may substantially correspond to an active area (or channel) of a transistor. In other words, a portion of the semiconductor pattern may be the active area of the transistor, another portion may be a source or a drain, and another portion may be a connection electrode or a signal connection line.

A first electrode S1, a channel unit A1, and a second electrode D1 of the first transistor T1 are provided from (or defined by portions of) the first semiconductor pattern. The first electrode S1 and the second electrode D1 of the first transistor T1 extend in opposite directions from the channel part A1.

FIG. 5A illustrates a portion of a connection signal line CSL electrically connected to the first semiconductor pattern. Although not separately illustrated, the connection signal line CSL may be connected to the second electrode of the fifth transistor T5 (see FIG. 5B) in a plan view.

A first insulation layer 10 may be disposed on the buffer layer BFL. The first insulation layer 10 may commonly overlap the plurality of pixels and cover the first semiconductor pattern. The first insulation layer 10 may include an inorganic material and/or organic material, and have a single layer or multilayer structure. The first insulation layer 10 may include at least one selected from aluminum oxide, titanium oxide, silicon oxide, silicon nitride, silicon oxynitride, zirconium oxide, or hafnium oxide. In the embodiment, the first insulation layer 10 may be a single layer of silicon oxide. In addition to the first insulation layer 10, an insulation layer of a circuit layer DP_CL to be described below may also be an inorganic layer and/or an organic layer, and have a single layer or multilayer structure. The inorganic layer may include at least one selected from the aforementioned materials, but is not limited thereto.

The circuit layer DP_CL may include the pixel driving circuit PDC (see FIG. 5B). For convenience of illustration and description, the first transistor T1 and a third transistor T3 of the pixel driving circuit PDC (see FIG. 5B) are shown.

A third electrode G1 of the first transistor T1 may be disposed on the first insulation layer 10. The third electrode G1 may be a portion of a metal pattern. The third electrode G1 of the first transistor T1 may overlap a channel unit A1 of the first transistor T1. The third electrode G1 of the first transistor T1 may serve as a mask in a process for doping the first semiconductor pattern. The third electrode G1 may include titanium (Ti), silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), indium zinc oxide (IZO), or the like, but is not particularly limited thereto.

A second insulation layer 20 may be disposed on the first insulation layer 10, and cover the third electrode G1 of the first transistor T1. The second insulation layer 20 may be an inorganic layer and/or organic layer, and have a single layer or multilayer structure. The second insulation layer 20 may include at least one of silicon oxide, silicon nitride, or silicon oxynitride. In an embodiment, the second insulation layer 20 may have a multilayer structure including silicon oxide layers and silicon nitride layers.

The upper electrode UE and a second rear-surface metal layer BMC2 may be disposed on the second insulation layer 20. The upper electrode UE may overlap with the third electrode G1. The upper electrode UE may be a portion of the metal pattern. A portion of the third electrode G1 and a portion of the upper electrode UE overlapping each other may define the capacitor Cst (see FIG. 5B). In an embodiment of the invention, the second insulation layer 20 may be replaced by an insulation pattern. In such an embodiment, the upper electrode UE may be disposed on the insulation pattern, and serve as a mask configured to provide the insulation pattern from the second insulation layer 20.

The second rear-surface metal layer BMC2 may be disposed under an oxide thin-film transistor, for example, the third transistor T3. The second rear-surface metal layer BMC2 may be applied with a constant voltage or a signal.

A third insulation layer 30 may be disposed on the second insulation layer 20, and cover the upper electrode UE and the second rear-surface metal layer BMC2. The third insulation layer 30 may have a single layer or multi-layer structure. In an embodiment, for example, the third insulation layer 30 may have a multilayer structure including silicon oxide layers and silicon nitride layers.

The second semiconductor pattern may be disposed on the third insulation layer 30. The second semiconductor pattern may include silicon oxide semiconductor. The silicon oxide semiconductor may include a plurality of areas divided according to whether a metal oxide is reduced. An area (hereinafter, a reduction area) in which the metal oxide is reduced has a higher conductivity than an area (hereinafter, a non-reduction area) in which the metal oxide is not reduced. The reduction are may substantially serve as a source/drain or a signal line of the transistor. The non-reduction area may substantially correspond to an active area (or a semiconductor area, a channel) of the transistor. In other words, a portion of the second semiconductor pattern may be the active area of the transistor, another portion may be the source/drain area of the transistor, and another portion may be a signal transfer area.

A first electrode S3, a channel unit A3, and a second electrode D3 of the third transistor T3 are provided from the second semiconductor pattern. The first electrode S3 and the second electrode D3 may include a metal reduced from a metal-oxide-semiconductor. The first electrode S3 and the second electrode D3 may extend in opposite directions from the channel unit A3 in a cross-sectional view.

A fourth insulation layer 40 may be disposed on the third insulation layer 30. The fourth insulation layer 40 may commonly overlap the plurality of pixels and cover the second semiconductor pattern. The fourth insulation layer 40 may include at least one selected from aluminum oxide, titanium oxide, silicon oxide, silicon nitride, silicon oxynitride, zirconium oxide, or hafnium oxide.

The third electrode G3 of the third transistor T3 may be disposed on the fourth insulation layer 40. The third electrode G3 may be a portion of a metal pattern. The third electrode G3 of the third transistor T3 may overlap the channel unit A3 of the third transistor T3. The third electrode G3 may serve as a mask in a process for doping the second semiconductor pattern. In an embodiment of the invention, a fourth insulation layer 40 may be replaced by an insulation pattern.

A fifth insulation layer 50 may be disposed on the fourth insulation layer 40 and cover the third electrode G3. The fifth insulation layer 50 may be an inorganic layer.

A first connection electrode CNE10 may be disposed on the fifth insulation layer 50. The first connection electrode CNE10 may be connected to the connection signal line CSL through a first contact hole CH1 defined or formed through the first to fifth insulation layers 10, 20, 30, 40 and 50.

A sixth insulation layer 60 may be disposed on the fifth insulation layer 50. The sixth insulation layer 60 may be an organic layer. The organic layer may include a general-purpose polymer such as benzocyclobutene (BCB), polyimide, hexamethyldisiloxane (HMDSO), polymethylmethacrylate (PMMA) or polystyrene (PS), a polymer derivative having a phenolic group, an acrylic-based polymer, an imide-based polymer, an aryl ether-based polymer, an amide-based polymer, a fluorinated polymer, a p-xylene-based polymer, a vinyl alcohol-based polymer, or a blend thereof, but is not particularly limited thereto.

A second connection electrode CNE20 may be disposed on the sixth insulation layer 60. The second connection electrode CNE20 may be connected to the first connection electrode CNE10 through a second contact hole CH2 defined or formed through the sixth insulation layer 60.

A seventh insulation layer 70 may be disposed on the sixth insulation layer 60 and cover the second connection electrode CNE20. A seventh insulation layer 70 may be an organic layer.

A first electrode layer may be disposed on the circuit layer DP-CL. A pixel definition layer PDL is provided on the first electrode layer. The first electrode layer may include an anode AE of the light-emitting element ED and an anode AE1 of the first sensing element OPD1. The anode AE of the light-emitting element ED and the anode AE1 of the first sensing element OPD1 may be disposed on the seventh insulation layer 70. The anode AE of the light-emitting element ED may be connected to the second connection electrode CNE20 through a third contact hole CH3 defined or formed through the seventh insulation layer 70. Namely, the light-emitting element ED may be electrically connected to the pixel driving circuit PDC (see FIG. 5B) provided on the circuit layer DP_CL.

A film opening PDL-OP is provided in the pixel definition layer PDL. The film opening PDL-OP exposes at least a portion of the anode AE of the light-emitting element ED. The pixel definition layer PDL may cover the anode AE1 of the first sensing element OPD1.

In an embodiment of the invention, the pixel definition layers PDL may further include a black material. The pixel definition layer PDL may further include a black organic dye/pigment such as carbon black, or aniline black. The pixel definition layer PDL may be provided with a mixture of a blue organic material and a black organic material. The pixel defined layer PDL may further include a lyophobic organic material. The pixel defined layer PDL may include an insulation material.

In an embodiment, as shown in FIG. 5A, the display panel DP may include an emission area PXA and a non-emission area NPXA adjacent to the emission area PXA. The non-emission area NPXA may surround the emission area PXA. In such an embodiment, the emission area PXA is defined in correspondence to a partial area of the anode AE exposed by the film opening PDL-OP.

A light-emitting layer EL may be disposed on the anode AE of the light-emitting element ED. The light-emitting layer EL may be disposed in an area corresponding to the film opening PDL-OP. The light emitting layer EL may generate prescribed colored light. In an embodiment, the light-emitting layer EL may be provided as a patterned light emitting layer EL, but not being limited thereto. In another embodiment, the light-emitting layer EL may be provided as one light emitting layer commonly disposed in the plurality of light emitting areas. Here, the light emitting layer may generate white light or blue light. In addition, the light emitting layer may have a multilayer structure referred to as tandem.

The light emitting layer EL may include a low molecular organic material or an organic polymer material as a light emitting material. Alternatively, the light emitting layer EL may include quantum dots as a light emitting material. The core of the quantum dot may be selected from a group II-VI compound, a group III-V compound, a group IV-VI compound, a group IV element, a group IV compound, or a combination thereof.

A cathode CE may be disposed on the light-emitting layer EL. In an embodiment, for example, the cathode CE may be commonly disposed in the emission area PXA, the non-emission area NPXA, and the non-pixel area NPA. The pixels PX and the first sensor FX1 may not be disposed in the non-pixel area NPA.

The circuit layer DP_CL may further include the first sensor driving circuit O_SD1 (see FIG. 5B). For convenience of illustration and description, the reset transistor ST1 in the first sensor driving circuit O_SD is illustrated in FIG. 5A. The reset transistor ST1 in the first sensor driving circuit O_SD1 may be referred to as a first rest transistor ST1.

A first electrode STS1, a channel unit STA1, and a second electrode STD1 of the reset transistor ST1 are provided from a second semiconductor pattern. The first electrode STS1 and the second electrode STD1 may include a metal reduced from a metal-oxide-semiconductor. The fourth insulation layer 40 may be disposed to cover the first electrode STS1, the channel unit STA1, and the second electrode STD1 of the reset transistor ST1. A third electrode STG1 of the reset transistor ST1 may be disposed on the fourth insulation layer 40. In an embodiment, the third electrode STG1 may be a portion of a metal pattern. The third electrode STG1 of the reset transistor ST1 may overlap the channel unit STA1 of the reset transistor ST1.

In an embodiment, for example, the reset transistor ST1 may be disposed in (or directly on) a same layer as the third transistor T3. In such an embodiment, the first electrode STS1, the channel unit STA1, and the second electrode STD1 of the reset transistor ST1 may be provided in a same process as the first electrode S3, the channel unit A3, and the second electrode D3 of the third transistor T3. The third electrode STG1 of the reset transistor ST1 may be provided concurrently in a same process as the third electrode G3 of the third transistor T3.

Although not separately illustrated, the first and second electrodes of the amplification transistor ST2 (see FIG. 5B) and the first and second electrodes of the output transistor ST3 (see FIG. 5B) of the first sensor driving circuit O_SD1 (see FIG. 5B) may be provided in a same process as the first and second electrodes S1 and D1 of the first transistor T1. The reset transistor ST1 and the third transistor T3 may be provided in (or directly on) a same layer in a same process, thereby not requiring additional processes for providing the reset transistor ST1. As a result, process efficiency may be increased and the cost may be reduced. The amplification transistor ST2 (see FIG. 5B) of the first sensor driving circuit O_SD1 (see FIG. 5B) may be referred to as a first amplification transistor ST2 (see FIG. 5B). The output transistor ST3 (see FIG. 5B) of the first sensor driving circuit O_SD1 (see FIG. 5B) may be referred to as a first output transistor ST3 (see FIG. 5B).

The element layer DP_ED may further include a first sensing element OPD1.

The first sensing element OPD1 may include an anode AE1, a semiconductor layer RL1, and a cathode CE1.

The anode AE1 of the first sensing element OPD1 may be disposed in (or directly on) a same layer as the anode AE of the light-emitting element. In such an embodiment, the anode AE1 may be disposed on the circuit layer DP_CL, and provided concurrently in a same process as the anode AE of the light-emitting element. The anode AE1 may be electrically connected through a separate wire from the reset transistor ST1. In such an embodiment, the anode AE1 may be electrically connected to the first sensor driving circuit O_SD1 (see FIG. 5B). The anode AE1 may be referred to as a first electrode AE1.

The pixel definition layer PDL may be disposed on the circuit layer DP_CL. The pixel definition layer PDL may cover the anode AE1.

The semiconductor layer RL1 may be disposed on the pixel definition layer PDL. The semiconductor layer RL1 may include an organic photo-sensing material. The semiconductor layer RL1 may be provided concurrently in a same process as the light-emitting layer EL of the light-emitting element ED.

In such an embodiment, as the pixel definition layer PDL is disposed between the anode AE1 and the semiconductor layer RL1, the anode AE1 and the semiconductor layer RL1 may be electrically open. In such an embodiment, the semiconductor layer RL1 may be electrically open with the first sensor driving circuit O_SD1 (see FIG. 5B).

The cathode CE1 may be disposed on the semiconductor layer RL1. The cathode CE1 may be electrically connected to the semiconductor layer RL1. The cathode CE1 of the first sensing element OPD1 may be provided concurrently in the same process as the cathode CE of the light-emitting element ED. In an embodiment, for example, the cathode CE1 may be integrally provided with the cathode CE. In such an embodiment, the light-emitting element ED may be electrically connected to the cathode CE1 of the first sensing element OPD1. The cathode CE1 may be referred to as a second electrode CE1.

In an embodiment, as shown in FIG. 5A, the display panel DP may further include a non-sensing area NSA. The non-sensing area NSA may be an area in which an external input is not sensed.

The encapsulation layer TFE may be disposed on the element layer DP_ED. The encapsulation layer TFE includes an inorganic layer or an organic layer. In an embodiment of the invention, the encapsulation layer TFE may include two inorganic layers and an organic layer interposed therebetween. In an embodiment of the invention, a thin-film encapsulation layer may include a plurality of inorganic layers and organic layers that are alternately laminated on each other.

The inorganic organic layer protects the light-emitting element ED and the first sensing element OPD1 from moisture/oxygen, and the organic encapsulation layer protects the same from foreign matters such as dust particles. The encapsulation inorganic layer may include a silicon nitride layer, a silicon oxynitride layer, a silicon oxide layer, a titanium oxide layer, aluminum oxide layer or the like, and is not particularly limited thereto. The encapsulation organic layer may include an acrylic-based inorganic layer, but is not particularly limited thereto.

The sensor layer SL may be disposed on the encapsulation layer TFE. The sensor layer SL may sense an external input applied from the outside. The sensor layer SL may also sense an external input by the user's body US_F.

The anti-reflection layer RPL may be disposed on the sensor layer SL. The anti-reflection layer RPL may include a black matrix layer BM and a color filter layer CF.

The black matrix layer BM may effectively prevent external light reflection from the sensor layer SL. Materials composing the black matrix layer BM are not particularly limited as long as the materials absorb light. The black matrix layer BM may have a black color and include a black coloring agent in an embodiment. The black coloring agent may include a block dye or a black pigment. The black coloring agent may include carbon black, a metal such as chromium, or an oxide thereof.

An opening BM-OP may be defined in the black matrix layer BM. The opening BPM-OP may overlap the light emitting layer EL. The black matrix layer BM may overlap the first sensing element OPD1. When viewed in a plan view or viewed in the third direction DR3, the black matrix layer BM may cover the first sensing element OPD1.

The color filter layer CF may be disposed on the black matrix layer BM and the sensor layer SL. The color filter layer CF may transmit light provided from the light-emitting layer EL overlapped with the color filter layer CF.

FIG. 5B is an equivalent circuit diagram of a pixel and a first sensor according to an embodiment of the invention.

FIG. 5B shows an example equivalent circuit diagram of one pixel PXij among the plurality of pixels PX (see FIG. 4). Since the plurality of pixels PX each have a same circuit structure as each other, the circuit structure of a pixel PXij will be described in detail and the description for the remaining pixels will be omitted. In addition, FIG. 5B shows an example equivalent circuit diagram of one first sensor FX1dj among the plurality of first sensors FX1 shown in FIG. 4. Since the plurality of first sensors FX1 each have a same circuit structure as each other, the description for the circuit structure of a first sensor FX1dj will be described in detail and the description for the remaining first sensors FX1 will be omitted.

Referring to FIGS. 5A and 5B, the pixel PXij is connected to an i-th data line DLi among the data lines DL1 to DLm, a j-th initialization scan line SILj among the initialization scan lines SIL1 to SILn, a j-th compensation scan line SCLj among the compensation scan lines SCL1 to SCLn, a j-th write scan line SWLj among the write scan lines SWL1 to SWLn, a j-th black scan line SBLj among the black scan lines SBL1 to SBLn, and a j-th emission control line EMLj among the emission control lines EML1 to EMLn.

The pixel PXij may include a light emitting element ED and a pixel driving circuit PDC. The light emitting element ED may include a light emitting diode. In an embodiment, for example, the light emitting element ED may be an organic light emitting diode including an organic light emitting layer, but is not particularly limited thereto.

The pixel driving circuit PDC includes first to fifth transistors T1, T2, T3, T4, and T5, first and second emission control transistors ET1 and ET2, and one capacitor Cst.

At least one of the first to fifth transistors T1, T2, T3, T4, and T5 and the first and second emission control transistors ET1 and ET2 may be a transistor having a low-temperature polycrystalline silicon (LTPS) semiconductor layer. At least one of the first to fifth transistors T1, T2, T3, T4, T5) and the first and second emission control transistors ET1, ET2 may be a transistor having an oxide semiconductor layer. For example, the third and fourth transistors T3 and T4 may be oxide semiconductor transistors, and the first, second, fifth transistors T1, T2, T5, and the first and second emission control transistors ET1, ET2 may be LTPS transistors.

In an embodiment, as the first transistor T1 configured to directly affect the brightness of the display device DD, the first transistor T1 may be configured to include a semiconductor layer including polycrystalline silicon with high reliability, thereby being capable of implementing a display device with high resolution. In such an embodiment, the oxide semiconductor has a high carrier mobility and a low leakage current, and thus a voltage drop is not large despite of a long drive time. In other words, a change in color of an image according to the voltage drop is not large even during low frequency driving, and thus the low frequency driving is possible. In this way, the oxide semiconductor may be desired in terms of small leak current, and thus at least one of the third transistor T3 connected to a gate electrode of the first transistor T1 and the fourth transistor T4 may be employed as an oxide semiconductor to effectively prevent the leak current capable of being flowed to the gate electrode, and to substantially reduce power consumption.

At least one of the first to fifth transistors T1, T2, T3, T4, and T5 and the first and second emission control transistors ET1 and ET2 may be P-type transistors, and others thereof may be N-type transistors. In an embodiment, for example, the first, second, fifth transistors T1, T2, and T5, and the first and second emission control transistors ET1 and ET2 may be P-type transistors, and the third and fourth emission control transistors T3 and T4 may be N-type transistors.

The configuration of the pixel driving circuit PDC according to an embodiment of the invention is not limited to the embodiment shown in FIG. 4B. The pixel driving circuit PDC shown in FIG. 5B is merely an example, and the configuration of the pixel circuit unit PDC may be modified. For example, all the first to fifth transistors T1, T2, T3, T4, and T5 and the first and second emission control transistors ET1 and ET2 may be P-type transistors or N-type transistors.

The j-th initialization scan line SILj, the j-th compensation scan line SCLj, the j-th write scan line SWLj, the j-th black scan line SBLj, and the j-th emission control line EMLj may respectively transfer, to the pixel PXij, a j-th initialization scan signal SIj, a j-th compensation scan signal SCj, a j-th write scan signal SWj, a j-th black scan signal SBj, and a j-th emission control signal EMj. The i-th data line DLi transfers an i-th data signal Di to the pixel PXij. The i-th data signal Di may have a voltage level corresponding to the image signal RGB (see FIG. 3) input to the display device DD.

The first and second driving voltage lines VL1 and VL2 may respectively transfer the first voltage ELVDD and the second driving voltage ELVSS to the pixel PXij. In addition, the first and second initialization voltage lines VL3 and VL4 may respectively transfer the first initialization voltage VINT1 and the second initialization voltage VINT2 to the pixel PXij.

The first transistor T1 is connected between the first driving voltage line VL1 that transfers the first driving voltage ELVDD and the light emitting element ED. The first transistor T1 includes a first electrode connected to the first driving voltage line VL1 via the first emission control transistor ET1, a second electrode connected to the anode AE of the light-emitting element ED via the second emission control transistor ET2, and a third electrode (e.g., a gate electrode) connected to one terminal (e.g., the first node N1) of the capacitor Cst. The first transistor T1 may receive the i-th data signal Di transferred by the i-th data line DLi according to a switching operation of the second transistor T2, and provide a driving current Id to the light-emitting element ED.

The second transistor T2 is connected between the data line DLi and the first electrode of the first transistor T1. The second transistor T2 includes a first electrode connected to the data line DLi, a second electrode connected to the first electrode of the first transistor T1, and a third electrode (e.g., a gate electrode) connected to the j-th write scan line SWLj. The second transistor T2 may be turned on in response to the write scan signal SWj transferred via the j-th write scan line SWLj to transfer the i-th data signal Di transferred from the i-th data line DLi to the first electrode of the first transistor T1.

The third transistor T3 is connected between the second electrode of the first transistor T1 and the first node N1. The third transistor T3 may include a first electrode connected to the third electrode of the first transistor T1, a second electrode connected to the second electrode of the first transistor T1, and a third electrode (e.g., a gate electrode) connected to the j-th compensation scan line SCLj. The third transistor T3 may be turned on in response to the j-th compensation scan signal SCLj transferred via the j-th compensation scan line SCLj to connect the third electrode and the second electrode of the first transistor T1, namely, diode-connect the first transistor T1.

The fourth transistor T4 is connected between the first node N1 and the first initialization voltage line VL3 applied with the first initialization voltage VINT1. The fourth transistor T4 may include a first electrode connected to the first initialization line VL3 that transfers the first initialization voltage VINT1, a second electrode connected to the first node N1, and a third electrode (e.g., a gate electrode) connected to the j-th initialization scan line SILj. The fourth transistor T4 is turned on in response to the j-th initialization scan signal SIj transferred via the j-th initialization scan line SILj. The turned-on fourth transistor T4 transfers the first initialization voltage VINT1 to the first node N1 to initialize a potential of the third electrode (i.e., the potential of the first node N1) of the first transistor T1.

The first emission control transistor ET1 includes a first electrode connected to the driving voltage line VL1, a second electrode connected to the first electrode of the first transistor T1, and a third electrode (e.g., a gate electrode) connected to the j-th emission control line EMLj.

The second emission control transistor ET2 may include a first electrode connected to the second electrode of the first transistor T1, a second electrode connected to the anode AE of the light-emitting element ED, and a third electrode (e.g., a gate electrode) connected to the j-th light emission control line EMLj.

The first and second emission control transistors ET1 and ET2 may be concurrently turned on in response to the j-th emission control signal EMj transferred via the j-th emission control line EMLj. The first driving voltage ELVDD applied via the turned-on first emission control transistor ET1 may be compensated via the diode-connected first transistor T1 and then transferred to the light-emitting element ED.

The fifth transistor T5 may include a first electrode connected to the second initialization line VL4 that transfers the second initialization voltage VINT2, a second electrode connected to the second electrode of the second emission control transistor ET2, and a third electrode (e.g., a gate electrode) connected to the j-th black scan line SBLj. The second initialization voltage VINT2 may have a voltage level not higher than the first initialization voltage VINT1.

As described above, one end of the capacitor Cst is connected to the third electrode of the first transistor T1, and the other end is connected to the first driving voltage line VL1. A cathode of the light-emitting diode ED may be connected to the second driving voltage line VL2 that transfers the second driving voltage ELVSS. The second driving voltage ELVSS may have a lower level than the first driving voltage ELVDD.

The sensor FX1dj is connected to a d-th readout line RLd among the readout lines RL1 to RLh, the j-th write scan line SWLj (or referred to as an output control line), and the reset control line RCL.

The first sensor FX1dj includes the first sensing element OPD1 and the first sensor driving circuit O_SD1.

The first sensing element OPD1 may be a photo diode. In an embodiment, for example, the sensing element OPD1 may be an organic photodiode OPD including an organic material in a photoelectric conversion layer. The anode AE1 of the first sensing element OPD1 may be connected to a first sensing node SN1, and a cathode CE1 of the first sensing element OPD1 may be connected to the second driving voltage line VL2 configured to transfer the second driving voltage ELVSS. In an embodiment, the pixel definition layer PDL is disposed between the anode AE1 and the cathode CE1 of the first sensing element OPD1, and thus the first sensing element OPD1 and the first sensor driving circuit O_SD1 may be electrically open or disconnected from each other.

FIG. 5B shows an embodiment where the sensor FX1dj includes one first sensing element OPD1, but the embodiment is not particularly limited thereto. In an embodiment, for example, the first sensor FX1dj may include z light receiving elements connected in parallel to each other. Here, z may be an integer of 2 or greater.

The first sensor driving circuit O_SD1 includes three transistors ST1, ST2, and ST3. The three transistors ST1, ST2, ST3 may be a reset transistor ST1, an amplification transistor ST2, and an output transistor ST3, respectively. At least one of the reset transistor ST1, the amplification transistor ST2, and the output transistor ST3 may be an oxide semiconductor transistor. In an embodiment, for example, the reset transistor ST1 may be an oxide semiconductor transistor, and the amplification transistor ST2 and the output transistor ST3 may be LTPS transistors. However, the embodiment of the invention is not limited thereto, and in another embodiment, the reset transistor ST1 and the output transistor ST3 may be oxide semiconductor transistors, and the amplification transistor ST2 may be an LTPS transistor, for example.

In addition, some of the reset transistor ST1, the amplification transistor ST2, and the output transistor ST3 may be P-type transistors, and the other may be an N-type transistor. In an embodiment of the invention, the amplification transistor ST2 and the output transistor ST3 may be P-type transistors and the reset transistor ST1 may be an N-type transistor. However, the embodiment is not limited thereto, and all the reset transistor ST1, the amplification transistor ST2, and the output transistor ST3 may be N-type transistors, or P-type transistors.

The reset transistor ST1 includes a first electrode connected to a third initialization voltage line VL5 that receives a first reset voltage Vrst1, a second electrode connected to the first sensing node SN1, and a third electrode that receives a reset control signal RST. The third electrode may be referred to as a gate electrode.

A cathode CE1 of the reset transistor ST1 may be electrically open with or disconnected from the first sensing element OPD1. The pixel definition layer PDL may be disposed between the anode AE1 of the first sensing element OPD1 and the semiconductor layer RL of the first sensing element OPD1 connected to the reset transistor ST1. Accordingly, the reset transistor ST1 and the first sensing element OPD1 may be electrically open or disconnected from each other.

The reset transistor ST1 may reset the potential of the first sensing node SN1 to the first reset voltage Vrst1 in response to the reset control signal RST. The reset control signal RST may be a signal provided through the reset control line RCL.

The amplification transistor ST2 includes a first electrode that receives the sensing driving voltage SLVD, a second electrode connected to the second sensing node SN2, and a third electrode connected to the first sensing node SN1. The amplification transistor ST2 may be turned on in response to the potential of the first sensing node SN1 to apply the sensing driving voltage SLVD to the second sensing node SN2. In an embodiment, for example, the sensing driving voltage SLVD may be one of the first driving voltage ELVDD and the first and second initialization voltages VINT1 and VINT2. In an embodiment where the sensing driving voltage SLVD is the first driving voltage ELVDD, the first electrode of the amplification transistor ST2 may be electrically connected to the first driving voltage line VL1. In an embodiment where the sensing driving voltage SLVD is the first initialization voltage VINT1, the first electrode of the amplification transistor ST2 may be electrically connected to the first initialization voltage line VL3. In an embodiment where the sensing driving voltage SLVD is the second initialization voltage VINT2, the first electrode of the amplification transistor ST2 may be electrically connected to the second initialization voltage line VL4.

The output transistor ST3 includes a first electrode connected to the second sensing node SN2, a second electrode connected to the d-th readout line RLd, and a third electrode that receives an output control signal. The output transistor ST3 may transfer a noise signal NSd to the d-th readout line RLD in response to the output control signal. The output control signal may be the j-th write scan signal SWj (or referred to as a j-th output control signal) provided through the j-th write scan line SWLj. In other words, the output transistor ST3 may receive, as the output control signal, the j-th write scan signal SWj provided from the j-th write scan line SWLj.

When the reset transistor ST1, the amplification transistor ST2, and the output transistor ST3 are driven, the noise signal NSd may be generated.

The noise signal NSd may include an electrical noise generated by the amplification transistor ST2.

The readout circuit 500 (see FIG. 3) having received the noise signal NSd may process the noise signal NSd to generate the noise-processed signal S_NS (see FIG. 3), and provide the noise-processed signal to the driving controller 100 (see FIG. 3).

According to an embodiment of the invention, the semiconductor layer RL1 that receives light to generate an electrical signal may be electrically open with (or disconnected from) the anode AE1 of the first sensing element OPD1. In such an embodiment, the black matrix layer BM disposed on the semiconductor layer RL1 may cover the semiconductor layer RL1 to block external light. In such an embodiment, the noise signal NSd provided through the readout line RLd may include only noise generated in the first sensor driving circuit O_SD1. The readout circuit 500 (see FIG. 3) may use the noise signal NSd to easily remove noise generated in a second sensor driving circuit O_SD2 (see FIG. 6B) from a signal measured by a second sensor FX2 (see FIG. 6B. Accordingly, the display device DD with improved sensing reliability may be provided.

FIG. 6A is a cross-sectional view of the display device taken along line II-II′ of FIG. 4 according to an embodiment of the invention. In describing the embodiment of FIG. 6A, like reference numerals are given to like elements shown in FIGS. 2 and 5A, and any repetitive detailed description thereof will be omitted.

Referring to FIG. 6A, in an embodiment, the circuit layer DP_CL may further include the second sensor driving circuit O_SD2 (see FIG. 6B). For convenience of illustration and description, the reset transistor ST1 in the second sensor driving circuit O_SD2 (see FIG. 6B) is shown. The reset transistor ST1 in the second sensor driving circuit O_SD may be referred to as a second rest transistor ST1.

A first electrode STS1, a channel unit STA1, and a second electrode STD1 of the reset transistor ST1 are provided from (or defined by portions of)_a second semiconductor pattern. The first electrode STS1 and the second electrode STD1 may include a metal reduced from a metal-oxide-semiconductor. The fourth insulation layer 40 is disposed to cover the first electrode STS1, the channel unit STA1, and the second electrode STD1 of the reset transistor ST1. The third electrode STG1 of the reset transistor ST1 is disposed on the fourth insulation layer 40. In an embodiment, the third electrode STG1 may be a portion of a metal pattern. The third electrode STG1 of the reset transistor ST1 may overlap the channel unit STA1 of the reset transistor ST1.

In an embodiment, for example, the reset transistor ST1 may be disposed in (or directly on) a same layer as the third transistor T3. In an embodiment, the first electrode STS1, the channel unit STA1, and the second electrode STD1 of the reset transistor ST1 may be provided in a same process as the first electrode S3, the channel unit A3, and the second electrode D3 of the third transistor T3. The third electrode STG1 of the reset transistor ST1 may be provided concurrently in a same process as the third electrode G3 of the third transistor T3.

Although not separately illustrated, the first and second electrodes of the amplification transistor ST2 (see FIG. 6B) and the first and second electrodes of the output transistor ST3 (see FIG. 6B) of the second sensor driving circuit O_SD2 (see FIG. 6B) may be provided in a same process as the first and second electrodes S1 and D1 of the first transistor T1. The reset transistor ST1 and the third transistor T3 may be provided in (or directly on) a same layer in a same process, without performing additional processes for providing the reset transistor ST1. As a result, process efficiency may be increased and the cost may be reduced. The amplification transistor ST2 (see FIG. 6B) of the second sensor driving circuit O_SD2 (see FIG. 6B) may be referred to as the second amplification transistor ST2 (see FIG. 6B). The output transistor ST3 (see FIG. 6B) of the second sensor driving circuit O_SD2 (see FIG. 6B) may be referred to as a second output transistor ST3 (see FIG. 6B).

The element layer DP_ED may further include a second sensing element OPD2.

The second sensing element OPD2 may include an anode AE2, a semiconductor layer RL2, and a cathode CE2.

The anode AE2 of the second sensing element OPD2 may be disposed in (or directly on) a same layer as the anode AE of the light-emitting element ED. In an embodiment, the anode AE2 may be disposed on the circuit layer DP_CL, and provided concurrently in a same process as the anode AE of the light-emitting element. The Anode AE2 may be electrically connected through a separate wire from the reset transistor ST1. In an embodiment, the anode AE2 may be electrically connected to the second sensor driving circuit O_SD2 (see FIG. 6B). The anode AE2 may be referred to as the first electrode AE2.

The pixel definition layer PDL may be disposed on the circuit layer DP_CL.

The first and second film openings PDL-OP1 and PDL-OP2 may be provided in the pixel definition layer PDL. The first film opening PDL-OP1 exposes at least a portion of the anode AE of the light-emitting element ED.

The second film opening PDL-OP2 of the pixel definition layer PDL exposes at least a portion of the anode AE2 of the second sensing element OPD2. The second semiconductor layer RL2 is disposed on the anode AE2 exposed by the second film opening PDL-OP. The semiconductor layer RL2 may include an organic photo-sensing material. The semiconductor layer RL2 may be provided concurrently with the light-emitting layer EL of the light-emitting element ED in a same process.

The cathode CE2 may be disposed on the semiconductor layer RL2. Each of the anode AE2 and the cathode CE2 may receive an electrical signal. The anode AE2 and the cathode CE2 may receive different signals, respectively. Accordingly, a prescribed electric field may be provided between the anode AE2 and the cathode CE2. The semiconductor layer RL2 may generate an electric signal corresponding to light incident to a sensor.

The cathode CE2 of the second sensing element OPD2 may be provided concurrently in a same process as the cathode CE of the light-emitting element ED. In an embodiment, for example, the cathode CE2 of the second sensing element OPD2 may be integrally provided with the cathode CE of the light-emitting element ED as a single unitary indivisible part. In such an embodiment, the light-emitting element ED may be electrically connected to the cathode CE2 of the second sensing element OPD2. The cathode CE2 may be referred to as a second electrode CE2.

Charges generated in the semiconductor layer RL2 changes the electric field between the anode AE2 and the cathode CE2. An amount of the charges generated in the semiconductor layer RL2 may be changed based on whether light is incident to the second sensing element OPD2, and the amount and intensity of the light incident to the second sensing element OPD2. Accordingly, the electric field provided between the anode AE2 and the cathode CE2 may be changed. The second sensing element OPD2 according to an embodiment of the invention may acquire information including user's fingerprint information or the like through the change in the electric field between the anode AE2 and the cathode CE2.

In an embodiment, as shown in FIG. 6A, the display panel DP may include a sensing area SA and a non-sensing area adjacent to the sensing area SA. The non-sensing area NSA may surround the sensing area SA. In an embodiment, the sensing area SA is defined as an area corresponding to a partial area of the anode AE2 exposed by the second film opening PDL-OP2.

The anti-reflection layer RPL may be disposed on the sensor layer SL. The anti-reflection layer RPL may include the black matrix layer BM and the color filter layer CF.

First and second openings BM-OP1 and BP-OP2 may be defined in the black matrix layer BM. The first opening BM-OP1 may overlap the light-emitting layer EL. The second opening BM-OP2 may overlap with semiconductor layer RL2. Light may be provided to the second sensor FX2 from the outside via the second opening BM-OP2.

The color filter layer CF may be disposed on the black matrix layer BM and the sensor layer SL. The color filter CF may transmit light provided from the light-emitting layer EL overlapping the color filter CF.

FIG. 6B is an equivalent circuit diagram of a pixel and a second sensor according to an embodiment of the invention. In describing the embodiment of FIG. 6B, like reference numerals are given to like elements shown in FIG. 5B, and any repetitive detailed description thereof will be omitted.

An example equivalent circuit diagram of one second sensor FX2dj among the plurality of second sensors FX2 shown in FIG. 4 is shown in FIG. 6B. Since the plurality of second sensors FX2 each have a same circuit structure as each other, the circuit structure of a second sensor FX2dj will be described in detail and the description for the remaining second sensors FX2 will be omitted.

Referring to FIGS. 6A and 6B, in an embodiment, the second sensor FX2dj includes the second sensing element OPD2 and the second sensor driving circuit O_SD2. The second sensor driving circuit O_SD2 may be substantially the same as the first sensor driving circuit O_SD1 (see FIG. 5B).

The second sensor FX2dj is connected to the d-th readout line RLd among the readout lines RL1 to RLh, the j-th write scan line SWLj (or referred to as an output control line), and the reset control line RCL.

The second electrode of the reset transistor ST1 may be electrically connected to the second sensing element OPD2.

The reset transistor ST1 may reset the potential of the first sensing node SN1 to the reset voltage Vrst1 in response to the reset control signal RST. The reset control signal RST may be a signal provided through the reset control line RCL.

The amplification transistor ST2 includes a first electrode that receives the sensing driving voltage SLVD, a second electrode connected to the second sensing node SN2, and a third electrode connected to the first sensing node SN1. The amplification transistor ST2 may be turned on in response to the potential of the first sensing node SN1 to apply the sensing driving voltage SLVD to the second sensing node SN2. In an embodiment, for example, the sensing driving voltage SLVD may be one of the first driving voltage ELVDD and the first and second initialization voltages VINT1 and VINT2. In an embodiment where the sensing driving voltage SLVD is the first driving voltage ELVDD, the first electrode of the amplification transistor ST2 may be electrically connected to the first driving voltage line VL1. In an embodiment where the sensing driving voltage SLVD is the first initialization voltage VINT1, the first electrode of the amplification transistor ST2 may be electrically connected to the first initialization voltage line VL3. In an embodiment where the sensing driving voltage SLVD is the second initialization voltage VINT2, the first electrode of the amplification transistor ST2 may be electrically connected to the second initialization voltage line VL4.

The output transistor ST3 includes a first electrode connected to the second sensing node SN2, a second electrode connected to the d-th readout line RLd, and a third electrode that receives the output control signal. The output transistor ST3 may transfer the readout signal FSd to the readout line RLd in response to the output control signal. The output control signal may be the j-th write scan signal SWj (or referred to as the j-th output control signal) provided through the j-th write scan line SWLj. In other words, the output transistor ST3 may receive, as the output control signal, the j-th write scan signal SWj provided from the j-th write scan line SWLj.

The reset period may be defined as a rising period (i.e., a high level period) of the reset control line RCL. In an embodiment, when the reset control signal RST of a high level is provided through the reset control line RCL, the reset transistor ST1 is turned on. In an embodiment where the reset transistor ST1 is a PMOS transistor, the reset control signal RST of a low level may be provided to the reset control line RCL during the reset period. During the reset period, the first sensing node SN1 may be reset to the potential corresponding to the reset voltage Vrst. In an embodiment, for example, the reset voltage Vrst may have a lower voltage level than the second driving voltage ELVSS.

The second sensing element OPD2 of the sensor FX2dj may be exposed to light during the emission period of the light-emitting element ED. Alternatively, the second sensing element OPD2 of the second sensor FX2dj may be exposed to external light. The voltage of the first sensing node SN1 is maintained as the reset voltage Vrst in the reset period, and as the second sensing element OPD2 is exposed to light, the voltage of the first sensing node SN1 may be gradually shifted to the second driving voltage ELVSS. The amplification transistor ST2 may be a source-follower amplifier configured to generate a source-drain current in proportion to a charge amount of the first sensing node SN1, which is input to the third electrode.

The output transistor ST3 may receive the j-th write scan signal SWj of a low level through the j-th write scan line SWLj in the output period. When the output transistor ST3 is turned on in response to the j-th write scan signal SWj of a low level, the readout signal Fsd corresponding to the current flowing through the amplification transistor ST2 may be output to the d-th readout line RLd.

A noise signal of the second sensor driving circuit O_SD2 may be further included in the readout signal FSd. The noise signal NSd (see FIG. 5B) of the second sensor driving circuit O_SD2 may be similar to that of the first sensor driving circuit O_SD1.

The readout circuit 500 (see FIG. 3) may receive the readout signal FSd, process the readout signal FSd to generate a sensing signal S_FS, and provide the sensing signal S_FS to the driving controller 100 (see FIG. 3).

According to an embodiment of the invention, the second electrode of the reset transistor ST1 (see FIG. 5A) may be electrically open with (or disconnected from) the first sensing element OPD1 (see FIG. 5A). Accordingly, the noise signal NSd (see FIG. 5B) of the first sensor driving circuit O_SD1 generated regardless of the first sensing element OPD1 (see FIG. 5A) may be measured with the first sensor FX1dj (see FIG. 5B). In addition, the second electrode of the reset transistor ST1 may be electrically connected to the second sensing element OPD2. Accordingly, the readout signal FSd including the noise signal of the second sensor driving circuit O_SD2 may be measured. The readout circuit 500 (see FIG. 3) may receive the noise signal NSd (see FIG. 5B) and the readout signal FSd, process each of the noise signal NSd (see FIG. 5B) and the readout signal FSd to generate the noise-processed signal S_NS (see FIG. 3) and the sensing signal S_FS (see FIG. 3), and provide the noise-processed signal S_NS (see FIG. 3) and the sensing signal S_FS (see FIG. 3) to the driving controller 100 (see FIG. 3). The driving controller 100 (see FIG. 3) may generate a noise-reduced signal based on the difference between the noise-processed signal S_NS and the sensing signal S_FS, e.g., by subtracting the noise-processed signal S_NS from the sensing signal S_FS. Accordingly, the display device DD with improved sensing reliability may be provided.

FIG. 7 is a cross-sectional view of a display device taken along line I-I′ of FIG. 4 according to another embodiment of the invention. In describing the embodiment of FIG. 7, like reference numerals are given to like elements shown in FIG. 5A, and any repetitive detailed description thereof will be omitted.

Referring to FIGS. 6A and 7, an embodiment of a display device DD-1 may include the display panel DP, the sensor layer SL, and an anti-reflection layer RPL-1. The anti-reflection layer RPL-1 may be disposed on the sensor layer SL. The anti-reflection layer RPL-1 may include a black matrix layer BM-1 and the color filter layer CF.

First and third openings BM-OP1, BM-OP2, and BM-OP3 may be defined in the black matrix layer BM-1. The first opening BM-OP1 may overlap the light-emitting layer EL. The third opening BM-OP3 may overlap the semiconductor layer RL1. In such an embodiment, the third opening BM-OP3 may overlap the first sensing element OPD1.

The color filter layer CF may be disposed on the black matrix layer BM and the sensor layer SL. The color filter CF may transmit light provided from the light-emitting layer EL overlapping the color filter CF.

According to an embodiment of the invention, the semiconductor layer RL1 that receives light to generate an electrical signal may be electrically open with the anode AE1 of the first sensing element OPD1. In such an embodiment, the noise signal NSd (see FIG. 5B) provided through the readout line RLd may include only noise generated in the first sensor driving circuit O_SD1 (see FIG. 5B). The readout circuit 500 (see FIG. 3) may use the noise signal NSd (see FIG. 5B) to easily remove, from a signal measured with the second sensor FX2, noise generated in the second sensor driving circuit O_SD2 (see FIG. 5B). Accordingly, the display device DD-1 with improved sensing reliability may be provided.

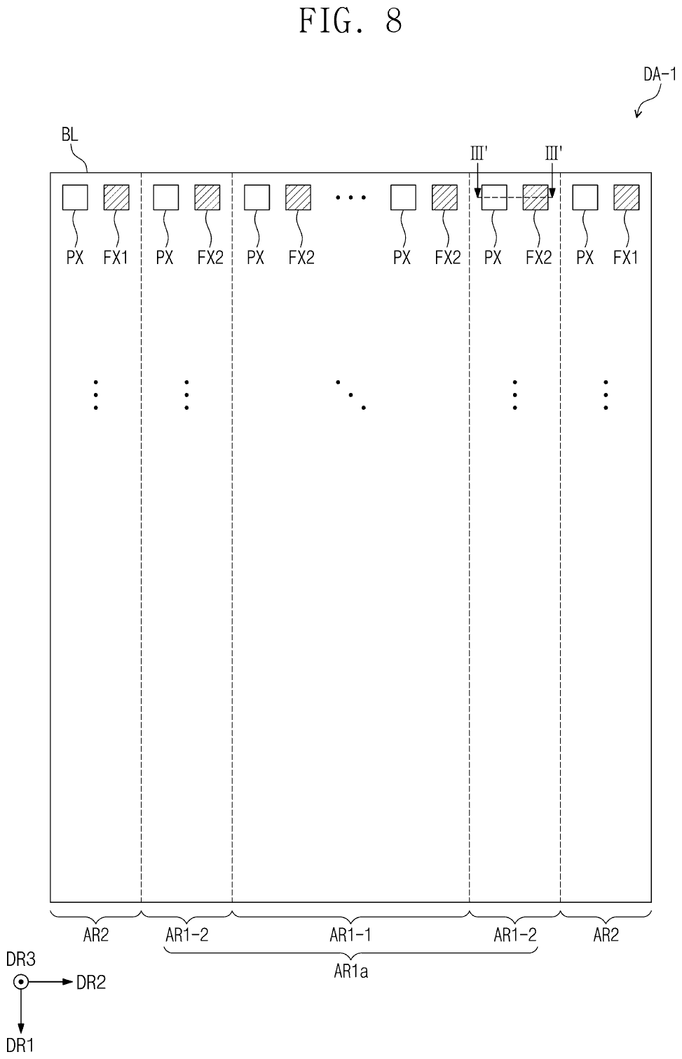

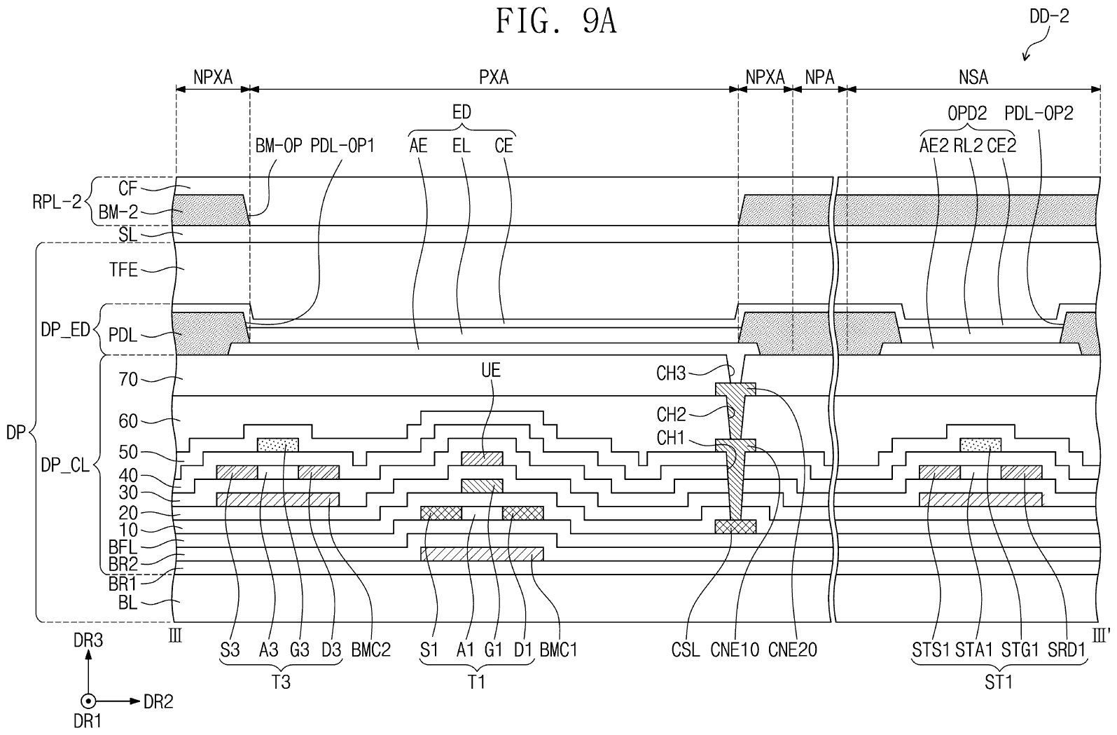

FIG. 8 is a plan view of a display area of a display panel according to an embodiment of the invention. In describing the embodiment of FIG. 8, like reference numerals are given to like elements shown in FIG. 3, and any repetitive detailed description thereof will be omitted.

Referring to FIG. 8, in an embodiment, a display area DA-1 may include a first area AR1a and a second area AR2. When viewed in a plan view or viewed in the third direction DR3, the base layer BL may overlap the display area DA-1. The display area DA-1 may be defined in the base layer BL. The first area AR1a and the second area AR2 may be defined in the base layer BL. The first area AR1a may include a first first area AR1-1 and a second first area AR1-2.

Each of the second area AR2 and the second first area AR1-2 may be provided in plural. One of the plurality of second areas AR2 may be positioned proximally from one of the plurality of second first areas AR1-2 in the opposite direction to the second direction DR2 Another one of the plurality of second areas AR2 may be positioned proximally from another one of the plurality of second first areas AR1-2 in the second direction DR2. The plurality of second first areas AR1-2 may be positioned between the plurality of second areas AR2.

One of the plurality of second first areas AR1-2 may be positioned proximally from the first first areas AR1-1 in the opposite direction to the second direction DR2. Another one of the plurality of second first areas AR1-2 may be positioned proximally from the first first area AR1-1 in the second direction DR2.

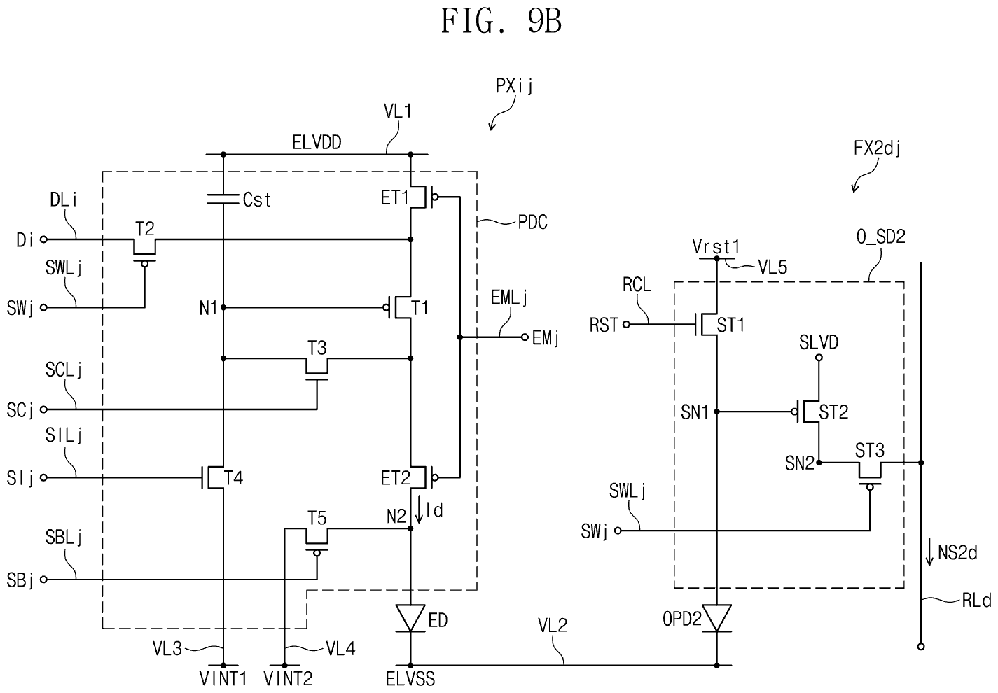

The plurality of pixels PX and the plurality of second sensors FX2 may be disposed in the first area AR1a. A display device DD-2 (see FIG. 9A) in the first first area AR1-1 may have a same laminated structure as that of the display device DD shown in FIG. 6A.

The plurality of pixels PX and the plurality of first sensors FX1 may be disposed in the second area AR2. The display device DD-2 (see FIG. 9A) in the second area AR2 may have a same laminated structure as that of the display device DD shown in FIG. 5.

FIG. 9A is a cross-sectional view of the display device taken along line III-III′ of FIG. 8 according to an embodiment of the invention. In describing the embodiment of FIG. 9A, like reference numerals are given to like elements shown in FIG. 6A, and any repetitive detailed description thereof will be omitted.

Referring to FIG. 9A, an embodiment of the display device DD-2 may include the display panel DP, the sensor layer SL, and an anti-reflection layer RPL-2. The anti-reflection layer RPL-2 may be disposed on the sensor layer SL. The anti-reflection layer RPL-2 may include a black matrix layer BM-2 and the color filter layer CF.

An opening BM-OP may be defined in the black matrix layer BM-2. The opening BPM-OP may overlap the light-emitting layer EL. The black matrix layer BM-2 may be disposed overlapping the second sensing element OPD2. When viewed in a plan view or viewed in the third direction DR3, the black matrix layer BM may cover the second sensing element OPD2.

The color filter layer CF may be disposed on the black matrix layer BM and the sensor layer SL. The color filter CF may transmit light provided from the light-emitting layer EL overlapping the color filter CF.

The display panel DP may further include the non-sensing area NSA. The non-sensing area NSA may be an area in which an external input is not sensed.

FIG. 9B is an equivalent circuit diagram of a pixel and a second sensor according to an embodiment of the invention. In describing the embodiment of FIG. 9B, like reference numerals are given to like elements shown in FIGS. 5B and 6B, and any repetitive detailed description thereof will be omitted.

FIG. 9B shows an example equivalent circuit diagram of one second sensor FX2dj among the plurality of second sensors FX2 disposed in the second first area AR1-2 shown in FIG. 8. Since each of the plurality of second sensors FX2 disposed on the second first area AR1-2 has a same circuit structure as each other, the circuit structure of a second sensor FX2dj will be described in detail and the description for the remaining second sensors FX2 will be omitted.

Referring to FIG. 9B, the second sensor FX2dj includes the second sensing element OPD2 and the second sensor driving circuit O_SD2.

The first sensor driving circuit O_SD1 includes three transistors ST1, ST2, and ST3. The three transistors ST1, ST2, ST3 may be a reset transistor ST1, an amplification transistor ST2, and an output transistor ST3, respectively.

The output transistor ST3 may transfer a second noise signal NS2d to the d-th readout line RLd in response to the output control signal. The output control signal may be the j-th write scan signal SWj (or referred to as the j-th output control signal) provided through the j-th write scan line SWLj. In other words, the output transistor ST3 may receive, as the output control signal, the j-th write scan signal SWj provided from the j-th write scan line SWLj.

The second noise signal NS2d may include an electrical noise generated in the second sensing element OPD2. External light may not be provided to the second sensing element OPD2 due to the black matrix layer BM-2. The second noise signal NS2d may be caused by dark current generated in the second sensing element OPD2.

The readout circuit 500 (see FIG. 3) may receive the second noise signal NS2d, process the second noise signal NS2d to generate the noise-processed signal S_NS (see FIG. 3), and provide the noise-processed signal S_NS to the driving controller 100 (see FIG. 3).

According to an embodiment of the invention, the second electrode of the reset transistor ST1 (see FIG. 5A) in the second area AR2 (see FIG. 8) may be electrically open with (or disconnected from) the first sensing element OPD1 (see FIG. 5A). Accordingly, the noise signal NSd (see FIG. 5B) of the first sensor driving circuit O_SD1 generated regardless of the first sensing element OPD1 (see FIG. 5A) may be measured. In addition, the second electrode of the reset transistor ST1 in the second first area AR1-2 may be electrically connected to the second sensing element OPD2, and when viewed in a plan view, the black matrix layer BM may cover the second sensing element OPD2. Accordingly, the second noise signal NS2d of the second sensing element OPD2 may be measured. In addition, the second electrode of the reset transistor ST1 in the first first area AR1-1 (see FIG. 8) may be electrically connected to the second sensing element OPD2. Accordingly, the readout signal FSd (see FIG. 6B) including the noise signal of the second sensing element OPD2 and the noise signal of the second sensor driving circuit O_SD2 may be measured.

In such an embodiment of the invention, the readout circuit 500 (see FIG. 3) may receive the noise signal NSd (see FIG. 5A), the second noise signal NS2d, and the readout signal FSd (see FIG. 6B), process each of the noise signal NSd (see FIG. 5A), the second noise signal NS2d, and the readout signal FSd (see FIG. 6B) to generate the noise-processed signal S_NS (see FIG. 3) and the sensing signal S_FS (see FIG. 3) to provide the noise-processed signal S_NS (see FIG. 3) and the sensing signal S_FS to the driving controller 100 (see FIG. 3). The driving controller 100 may subtract the noise-processed signal S_NS from the sensing signal S_FS to obtain a noise-reduced signal. Accordingly, the display device DD (see FIG. 3) with improved sensing reliability may be provided.

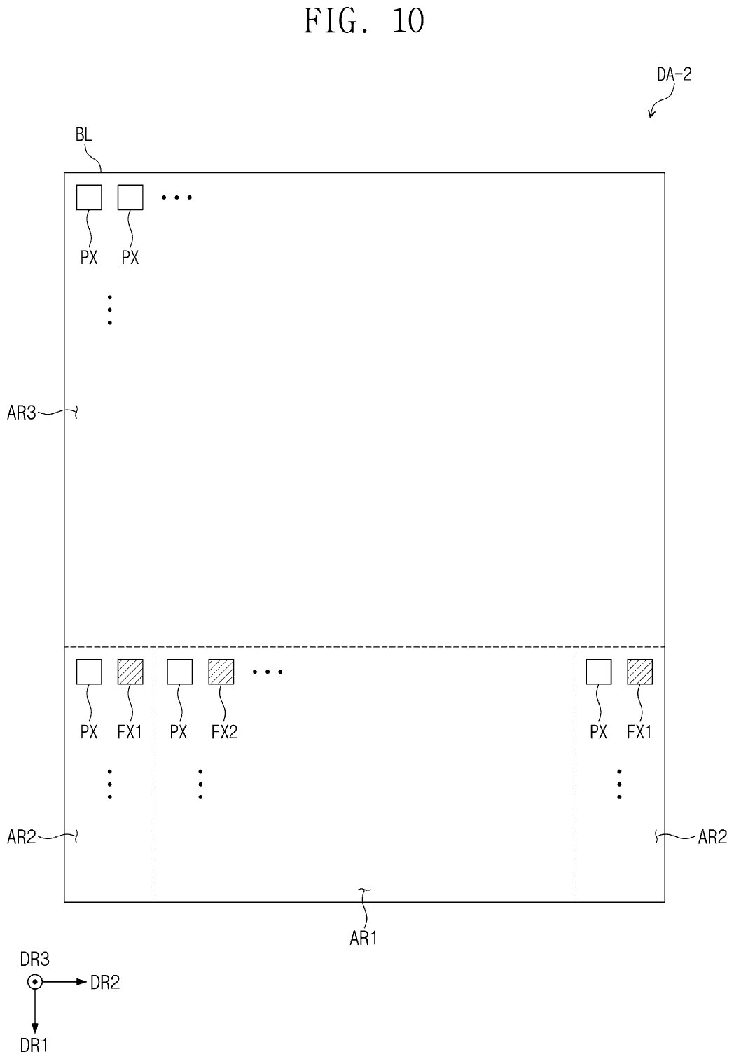

FIG. 10 is a plan view of a display area of a display panel according to an embodiment of the invention. In describing the embodiment of FIG. 10, like reference numerals are given to like elements shown in FIG. 4, and any repetitive detailed description thereof will be omitted.

Referring to FIG. 10, a display area DA-2 may include the first area AR1, the second area AR2, and a third area AR3. When viewed in a plan view, the base layer BL may overlap the display area DA-2. The display area DA-2 may be defined in the base layer BL. The first area AR1, the second area AR2, and the third area AR3 may be defined in the base layer BL.

The third area AR3 may be positioned proximally from the plurality of second areas AR2 and the first area AR1 in the opposite direction to the first direction DR1. Only the plurality of pixels PX may be disposed in the third area AR3.

FIG. 11 is an equivalent circuit diagram of a pixel and a first sensor according to an embodiment of the invention. In describing the embodiment of FIG. 11, like reference numerals are given to like elements shown in FIG. 5B, and any repetitive detailed description thereof will be omitted.

Referring to FIGS. 5A and 11, in an embodiment, a first sensor FX1dj-1 includes the first sensing element OPD1 and a first sensor driving circuit O_SD1-1.

The first sensor driving circuit O_SD1-1 includes three transistors ST1-1, ST2, and ST3. The three transistors ST1-1, ST2, and ST3 may be respectively a reset transistor ST1-1, the amplification transistor ST2, and the output transistor ST3.

The reset transistor ST1-1 includes a first electrode connected to a third initialization voltage line VL5-1 that receives the second reset voltage Vrst2, a second electrode connected to the first sensing node SN1, and a third electrode that receives the reset control signal RST. The third electrode may be referred to as a gate electrode.

The second electrode of the reset transistor ST1-1 may be electrically connected to the first sensing element OPD1. The pixel definition layer PDL may be disposed between the anode AE1 of the first sensing element OPD1 and the semiconductor layer RL of the first sensing element OPD1 connected to the reset transistor ST1-1. Accordingly, the reset transistor ST1-1 and the first sensing element OPD1 may be electrically open or disconnected from each other.

The reset transistor ST1-1 may reset the potential of the first sensing node SN1 to the second reset voltage Vrst2 having a different voltage level from the first reset voltage Vrst1 (see FIG. 6B) in response to the reset control signal RST. The reset control signal RST may be a signal provided through the reset control line RCL.

When the reset transistor ST1-1, the amplification transistor ST2, and the output transistor ST3 are driven, a noise signal NSd-1 may be generated.

The noise signal NSd-1 may include an electrical noise generated from the amplification transistor ST2.

The readout circuit 500 (see FIG. 3) having received the noise signal NSd-1 may process the noise signal NSd-1, generate the noise-processed signal S_NS (see FIG. 3), and provide the noise-processed signal S_NS to the driving controller 100 (see FIG. 3).

According to an embodiment of the invention, the second reset voltage Vrst2 having a different voltage level from the first reset voltage Vrst1 (see FIG. 6B) applied to the reset transistor ST1 (see FIG. 6B) in the first area AR1 (see FIG. 4) may be applied to the reset transistor ST1-1 in the second area AR2 (see FIG. 4). The noise signal NSd-1 set to correspond to the noise generated in the second sensor driving circuit O_SD2 (see FIG. 6B) may be provided by applying the second reset voltage Vrst2 to the first sensor driving circuit O_SD1-1. The readout circuit 500 (see FIG. 3) may use the noise signal NSd-1 to easily remove the noise generated in the second sensor driving circuit O_SD2 (see FIG. 6B) from the readout signal FSd (see FIG. 6B) measured with the second sensor FX2 (see FIG. 6B). Accordingly, the display device DD (see FIG. 3) with improved sensing reliability may be provided.

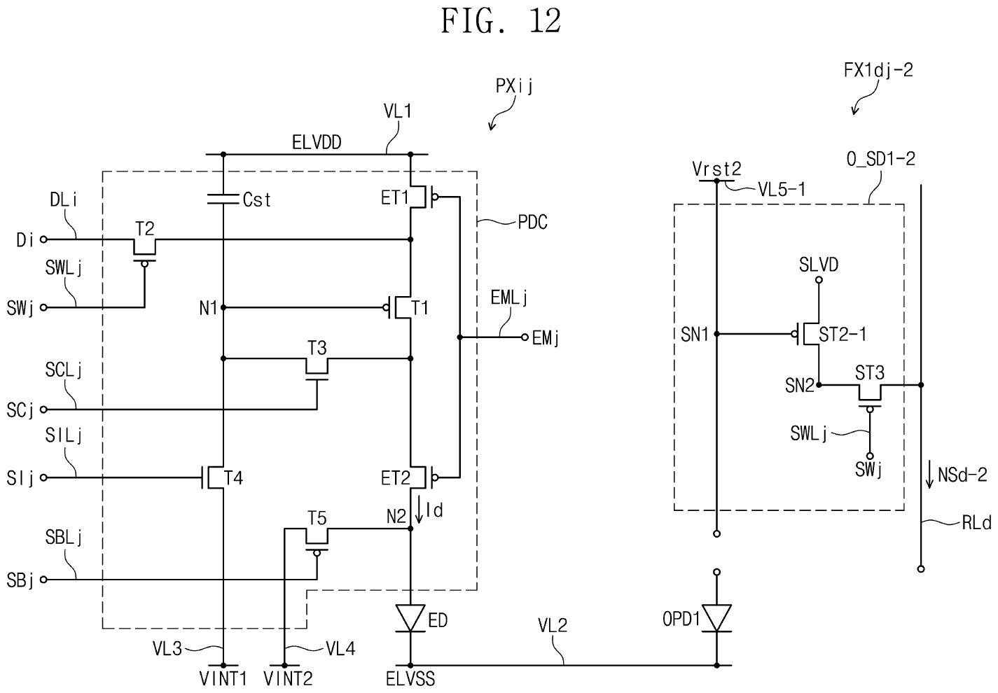

FIG. 12 is an equivalent circuit diagram of a pixel and a first sensor according to an embodiment of the invention. In describing the embodiment of FIG. 12, like reference numerals are given to like elements shown in relation to FIG. 5B, and any repetitive detailed description thereof will be omitted.

Referring to FIGS. 5A and 12, in an embodiment, a first sensor FX1dj-2 includes the first sensing element OPD1 and a first sensor driving circuit O_SD1-2.

The first sensor driving circuit O_SD1-2 includes two transistors ST2-1 and ST3. The two transistors ST2-1 and ST3 may be respectively an amplification transistor ST2-1 and the output transistor ST3.

The amplification transistor ST2-1 includes a first electrode that receives the sensing driving voltage SLVD, a second electrode connected to the second sensing node SN2, and a gate electrode connected to the first sensing node SN1. The first sensing node SN1 may be connected to the third initialization voltage line VL5-1 that receives the second reset voltage Vrst2. In an embodiment, for example, the gate electrode of the amplification transistor ST2-1 may be directly connected to the third initialization voltage line VL5-1. The second reset voltage Vrst2 may have a different voltage level from the first reset voltage Vrest1 (see FIG. 6B).

The amplification transistor ST2-1 may be turned on in response to the potential of the first sensing node SN1 to apply the sensing driving voltage SLVD to the second sensing node SN2. In an embodiment, for example, the sensing driving voltage SLVD may be one of the first driving voltage ELVDD and the first and second initialization voltages VINT1 and VINT2. In an embodiment where the sensing driving voltage SLVD is the first driving voltage ELVDD, the first electrode of the amplification transistor ST2-1 may be electrically connected to the first driving voltage line VL1. In an embodiment where the sensing driving voltage SLVD is the first initialization voltage VINT1, the first electrode of the amplification transistor ST2-1 may be electrically connected to the first initialization voltage line VL3. In an embodiment where the sensing driving voltage SLVD is the second initialization voltage VINT2, the first electrode of the amplification transistor ST2-1 may be electrically connected to the second initialization voltage line VL4.

The gate electrode of the amplification transistor ST2-1 may be electrically connected to the first sensing element OPD1. The pixel definition layer PDL may be disposed between the anode AE1 of the first sensing element OPD1 and the semiconductor layer RL of the first sensing element OPD1 connected to the amplification transistor ST2-1. Accordingly, the amplification transistor ST2-1 and the first sensing element OPD1 may be electrically open or disconnected from each other.

The output transistor ST3 include a first electrode connected to the second sensing node SN2, a second electrode connected to the d-th readout line RLd, and a third electrode that receives the output control signal. The output transistor ST3 may transfer a noise signal NSd-2 to the d-th readout line RLD in response to the output control signal. The output control signal may be the j-th write scan signal SWj (or referred to as the j-th output control signal) provided through the j-th write scan line SWLj. In other words, the output transistor ST3 may receive, as the output control signal, the j-th write scan signal SWj provided from the j-th write scan line SWLj.

When the amplification transistor ST2-1 and the output transistor ST3 are driven, the noise signal NSd-2 may be generated. The noise signal NSd-2 may include an electrical noise generated by the amplification transistor ST2-1.

The readout circuit 500 (see FIG. 3) may receive the noise signal NSd-2, process the noise signal NSd-2 to generate the noise-processed signal S_NS (see FIG. 3), and provide the noise-processed signal S_NS to the driving controller 100 (see FIG. 3).

According to an embodiment of the invention, regardless of the reset control signal applied to the reset transistor, the second reset voltage Vrst2 may be directly applied to the gate electrode of the amplification transistor ST2-1. The noise signal NSd-2 set to correspond to the noise generated in the second sensor driving circuit O_SD2 (see FIG. 6B) may be provided. The readout circuit 500 (see FIG. 3) may use the noise signal NSd-2 to easily remove the noise generated in the second sensor driving circuit O_SD2 (see FIG. 6B) from the readout signal FSd (see FIG. 6B) measured with the second sensor FX2dj (see FIG. 6B). Accordingly, the display device DD (see FIG. 3) with improved sensing reliability may be provided.

According to embodiments of the invention, as described herein, the semiconductor layer that receives light to generate an electrical signal may be electrically open with or disconnected from the anode of the first sensing element. In such embodiments, the black matrix layer disposed on the semiconductor layer may cover the semiconductor layer to block light from the outside. Accordingly, only a noise signal generated from the first sensor driving circuit may be measured. The readout circuit may use the noise signal to easily remove, from the signal measured by the second sensor, a noise generated by the second sensor driving circuit. Accordingly, a display device with improved reliability may be provided.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel including a display area defined therein,
wherein the display panel comprises:
a pixel comprising a pixel driving circuit and a light-emitting element; and
a first sensor comprising a first sensor driving circuit and a first sensing element,
wherein the first sensing element comprises a first electrode electrically connected to the first sensor driving circuit, a semiconductor layer electrically disconnected from the first electrode, and a second electrode electrically connected to the semiconductor layer, and
wherein the light-emitting element is electrically connected to the pixel driving circuit and the second electrode.

2. The display device of claim 1, wherein
the display panel further comprises a second sensor comprising a second sensor driving circuit and a second sensing element different from the first sensing element,
a first area and a second area adjacent to the first area are defined in the display area, and
the second sensor is disposed in the first area.

3. The display device of claim 2, wherein the second sensing element comprises a first electrode electrically connected to the second sensor driving circuit, a semiconductor layer electrically connected to the first electrode, and a second electrode electrically connected to the semiconductor layer.

4. The display device of claim 2, wherein the first sensor is disposed in the second area.

5. The display device of claim 3, wherein the second sensor driving circuit comprises:
a second reset transistor comprising a gate electrode which receives a reset control signal, a first electrode which receives a first reset voltage, and a second electrode connected to a first sensing node therein;
a second amplification transistor comprising a first electrode which receives a sensor driving voltage, a second electrode connected to a second sensing node therein, and a gate electrode connected to the first sensing node therein; and
a second output transistor comprising a first electrode connected to the second sensing node therein, a second electrode connected to a readout line, and a gate electrode which receives an output control signal.

6. The display device of claim 5, wherein the first sensor driving circuit comprises:
a first reset transistor comprising a gate electrode which receives the reset control signal, a first electrode, and a second electrode connected to a first sensing node therein;
a first amplification transistor comprising a first electrode which receives the sensor driving voltage, a second electrode connected to a second sensing node therein, and a gate electrode connected to the first sensing node therein; and
a first output transistor comprising a first electrode connected to the second sensing node therein, a second electrode connected to the readout line, and a gate electrode which receives the output control signal.

7. The display device of claim 6, wherein the first reset voltage is provided to the first electrode of the first reset transistor.

8. The display device of claim 6, wherein a second reset voltage having a different voltage level from the first reset voltage is provided to the first electrode of the first reset transistor.

9. The display device of claim 5, wherein the first sensor driving circuit comprises:
a first amplification transistor comprising a first electrode which receives the sensor driving voltage, a second electrode connected to a second sensing node therein, and a gate electrode connected to a second reset voltage having a different voltage level from the first reset voltage; and
a first output transistor comprising a first electrode connected to the second sensing node therein, a second electrode connected to the readout line, and a gate electrode which receives the output control signal.

10. The display device of claim 2, further comprising:
an anti-reflection layer disposed on the display panel,
wherein the anti-reflection layer comprises:
a black matrix layer having a first opening overlapping the light-emitting element therein when viewed in a plan view; and
a color filter layer disposed on the first opening.

11. The display device of claim 10, wherein when viewed in the plan view, a second opening overlapping the second sensing element is defined in a black matrix layer.

12. The display device of claim 11, wherein when viewed in the plan view, a third opening overlapping the first sensing element is defined in the black matrix layer.

13. The display device of claim 10, wherein when viewed in the plan view, the black matrix layer overlaps the first sensing element.

14. The display device of claim 13, wherein
the first area comprises a first first area and a second first area disposed between the first first area and the second area,
a second opening overlapping the second sensing element is defined in the black matrix layer in the first first area, and
the black matrix layer overlaps the second sensing element in the second first area.

15. The display device of claim 2, wherein
a third area adjacent to the first area and the second area is defined in the display area, and
each of the first sensor and the second sensor is spaced apart from the third area.

16. A display device comprising:
a base layer;
a circuit layer disposed on the base layer and comprising a pixel driving circuit and a first sensor driving circuit;
an element layer disposed on the circuit layer and comprising a light-emitting element, a first sensing element, and a pixel definition layer; and
an encapsulation layer disposed on the element layer,
wherein the first sensing element comprises a first electrode disposed on the circuit layer and covered with the pixel definition layer, a semiconductor layer disposed on the pixel definition layer, and a second electrode covering the semiconductor layer.

17. The display device of claim 16, wherein
a first area and a second area adjacent to the first area are defined on the base layer, and
the first sensor driving circuit and the first sensing element are disposed in the second area.

18. The display device of claim 16, wherein the first sensor driving circuit comprises:
a first reset transistor comprising a gate electrode which receives a reset control signal, a first electrode, and a second electrode connected to a first sensing node therein;
a second amplification transistor comprising a first electrode which receives a sensor driving voltage, a second electrode connected to a second sensing node therein, and a gate electrode connected to the first sensing node; and
a first output transistor comprising a first electrode connected to the second sensing node therein, a second electrode connected to a readout line, and a gate electrode which receives an output control signal.

19. The display device of claim 18, wherein a first reset voltage is provided to the first electrode of the first reset transistor.

20. The display device of claim 16, wherein the first sensor driving circuit comprises:
a first amplification transistor comprising a first electrode which receives a sensor driving voltage, a second electrode connected to a second sensing node therein, and a gate electrode which receives a second reset voltage; and
a first output transistor comprising a first electrode connected to the second sensing node therein, a second electrode connected to a readout line, and a gate electrode which receives an output control signal.
